(19) United States
(12) Patent Application Publication
(10) Pub. No.: US 2026/0040769 A1
(43) Pub. Date: Feb. 5, 2026

(54) DISPLAY PANEL, MANUFACTURING METHOD OF DISPLAY PANEL, AND DISPLAY DEVICE

(71) Applicants: Hefei Visionox Technology Co., Ltd., Hefei (CN); VISIONOX TECHNOLOGY INC., Jiangsu (CN)

(72) Inventors: Yuan YAO, Hefei (CN); Chung-Chun LEE, Hefei (CN); Deng GAO, Hefei (CN); Yuting FU, Hefei (CN)

(73) Assignees: Hefei Visionox Technology Co., Ltd., Hefei (CN); VISIONOX TECHNOLOGY INC., Jiangsu (CN)

(21) Appl. No.: 19/268,053

(22) Filed: Jul. 14, 2025

(30) Foreign Application Priority Data
Aug. 2, 2024 (CN) 202411061611.7

(51) Int. Cl. H10K 59/122; H10K 59/12; H10K 59/35

(52) U.S. Cl. CPC H10K 59/122; H10K 59/1201; H10K 59/353

(57) ABSTRACT

A display panel, a manufacturing method of the display panel, and a display device. The display panel includes a substrate; a pixel defining layer disposed on a side of the substrate and including a pixel defining portion and a plurality of pixel openings formed by enclosing the pixel defining portion; an isolation structure disposed on the side of the substrate, where a plurality of isolation openings are disposed on the isolation structure, and the plurality of isolation openings communicate with the plurality of pixel openings; a plurality of light-emitting devices at least partially located within the plurality of pixel openings, where the pixel defining portion exposed from at least part of the plurality of isolation openings has a dimple structure disposed on a side facing away from the substrate.

### CROSS-REFERENCE TO RELATED APPLICATION

This application claims priority to Chinese Patent Application No. 202411061611.7 filed Aug. 2, 2024, the disclosure of which is incorporated herein by reference in its entirety.

### TECHNICAL FIELD

The present disclosure belongs to the field of display technologies, and in particular to, a display panel, a manufacturing method of the display panel, and a display device.

### BACKGROUND

Organic light-emitting diodes (OLEDs) and planar display devices based on technologies such as light-emitting diode (LED) technology are widely used in various consumer electronic products such as a mobile phone, a television, a notebook computer, and a desktop computer because of advantages such as high picture quality, power saving, a thin body, and a wide application scope, and have become the mainstream in display devices.

However, the manufacturing process and display performance of current OLED display products need to be improved.

### SUMMARY

Embodiments of the present disclosure provide a display panel, a manufacturing method of the display panel, and a display device, to improve the display effect of the display panel.

An embodiment of a first aspect of the present disclosure provides a display panel. The display panel includes a substrate, a pixel defining layer, an isolation structure and a plurality of light-emitting devices. The pixel defining layer is disposed on a side of the substrate and includes a pixel defining portion and a plurality of pixel openings formed by enclosing the pixel defining portion. The isolation structure is disposed on a side of the substrate, a plurality of isolation openings are disposed on the isolation structure, and the plurality of isolation openings communicate with the plurality of pixel openings. The plurality of light-emitting devices are at least partially located within the pixel opening. The pixel defining portion exposed from at least part of the plurality of isolation openings has a dimple structure on a side of the pixel defining portion facing away from the substrate.

An embodiment of a first aspect of the present disclosure further provides a display panel. The display panel includes a substrate, an isolation structure and a plurality of light-emitting devices. The isolation structure disposed on a side of the substrate, a plurality of isolation openings are disposed on the isolation structure, the isolation structure includes a first isolation portion and a conductive portion disposed on a side of the first isolation portion towards the substrate, and the conductive portion has a second protrusion portion disposed to protrude from the first isolation portion that protrudes towards the plurality of isolation openings. The plurality of light-emitting devices are at least partially located within the isolation opening. The second protrusion portion of at least part of the conductive portion has a dimple structure disposed on a side of the second protrusion portion facing away from the substrate.

An embodiment of a second aspect of the present disclosure provides a manufacturing method of a display panel. The manufacturing method includes that: an isolation material layer is formed on a substrate; a first opening and a second opening that penetrate through the isolation material layer are provided; a first-type device is disposed within the first opening; a second-type device is disposed within the second opening, where the first-type device and the second-type device have different light-emitting colors; a third opening that penetrates through the isolation material layer is provided; and a third-type device is disposed within the third opening.

In the display panel provided in the embodiments of the present disclosure, the display panel includes the substrate, the pixel defining layer, the isolation structure and the light-emitting device. The pixel defining layer includes the pixel defining portion and the plurality of pixel openings formed by enclosing the pixel defining portion. The plurality of light-emitting devices are at least partially located within the pixel opening. The isolation structure is disposed on one side of the substrate and is formed with the plurality of isolation openings by enclosing the isolation structure, where the plurality of isolation openings communicate with the plurality of pixel openings. The pixel defining layer and the isolation structure may be configured to divide sub-pixels of the display panel. The pixel defining portion exposed from at least part of the plurality of isolation openings has the dimple structure disposed on one side of the pixel defining portion facing away from the substrate, so that the display effect of the display panel can be improved.

### BRIEF DESCRIPTION OF DRAWINGS

In order to more clearly explain the technical solutions in embodiments of the present disclosure, the drawings used for describing the embodiments of the present disclosure will be briefly introduced below. Obviously, the drawings in the following description are merely some embodiments of the present disclosure. For those of ordinary skill in the art, other drawings may also be obtained without creative labor according to these drawings.

FIG. 1 is a partial schematic diagram of an isolation structure according to an embodiment of the present disclosure;

FIG. 1A is a partial schematic diagram of a pixel defining layer according to an embodiment of the present disclosure;

FIG. 2 is a partial sectional view of a display panel according to an embodiment of the present disclosure;

FIG. 2A is a partial enlarged sectional view of a display panel according to an embodiment of the present disclosure;

FIG. 3 is a partial sectional view of a display panel according to another embodiment of the present disclosure;

FIG. 3A is a partial enlarged sectional view of a display panel according to another embodiment of the present disclosure;

FIG. 4 is a partial sectional view of a display panel according to still another embodiment of the present disclosure;

FIG. 5 is a partial sectional view of a display panel according to another embodiment of the present disclosure;

FIG. 6 is a partial sectional view of a display panel according to another embodiment of the present disclosure;

FIG. 7 is a partial sectional view of a display panel according to another embodiment of the present disclosure;

FIG. 8 is a partial sectional view of a display panel according to another embodiment of the present disclosure;

FIG. 9 is a schematic flowchart of a manufacturing method of a display panel according to an embodiment of the present disclosure;

FIG. 10 to FIG. 36 are schematic diagrams of a manufacturing process of a manufacturing method of a display panel according to an embodiment of the present disclosure;

FIG. 37 is a schematic flowchart of a manufacturing method of a display panel according to an embodiment of the present disclosure; and

FIG. 38 to FIG. 44 are schematic diagrams of a manufacturing process of a manufacturing method of a display panel according to an embodiment of the present disclosure.

### DETAILED DESCRIPTION

In this specification, relational terms such as first and second are only used to distinguish one entity or operation from another entity or operation, and do not require or imply any actual relationship or sequence between these entities or operations. Furthermore, the terms “include”, “contain”, or any other variant thereof are intended to cover a non-exclusive inclusion, so that a process, a method, an article, or a device that includes a series of elements not only includes those elements, but also includes other elements that are not explicitly listed, or further includes elements inherent to the process, the method, the article, or the device. An element defined by the sentence “include . . . ” does not exclude that another same element exists in a process, a method, an article, or a device that includes the element, without more limitation.

In describing the structure of the component, when one layer or one region is referred to as being “on” or “over” another layer or another region, it may mean that one layer or one region is directly on another layer or another region or that one layer or one region includes other layers or regions between the one layer or the one region and the another layer or the another region. Moreover, if the component is flipped, one layer or one region will be “under” or “below” another layer or another region.

Embodiments of the present disclosure provide a display panel, a manufacturing method of the display panel, and a display device. Various embodiments of the display panel, the manufacturing method of the display panel, and the display device below in conjunction with the accompanying drawings.

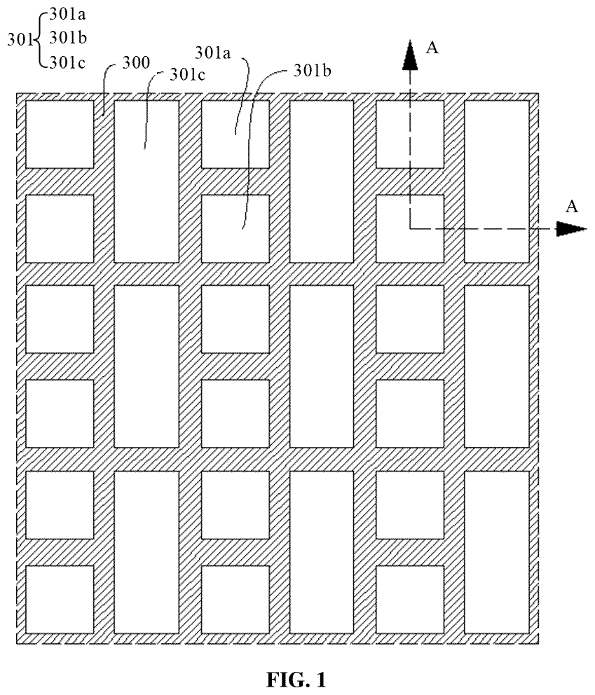

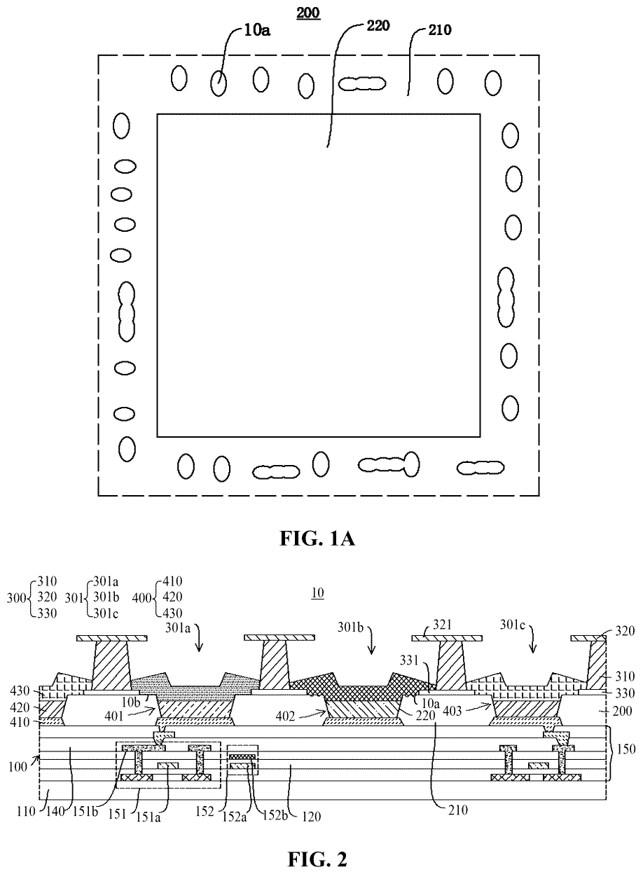

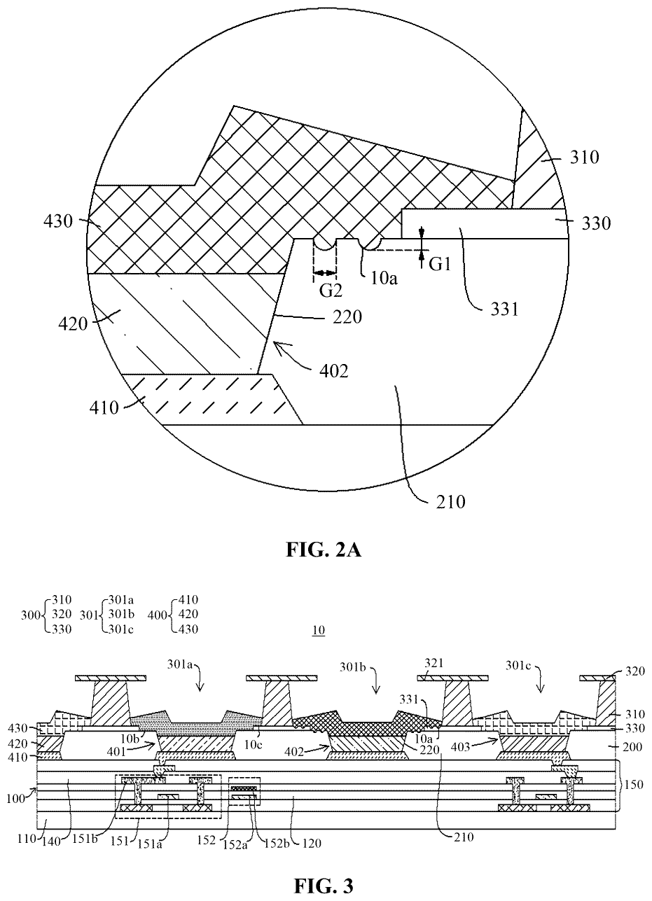

FIG. 1 is a partial schematic diagram of an isolation structure 300 according to an embodiment of the present disclosure, FIG. 1A is a partial schematic diagram of a pixel defining layer 200 according to an embodiment of the present disclosure, FIG. 2 is a partial sectional view of a display panel 10 according to an embodiment of the present disclosure, and FIG. 2A is a partial enlarged sectional view of a display panel 10 according to an embodiment of the present disclosure. FIG. 2A may be a partial enlarged view of a second opening 301b of FIG. 2. A partial cross-sectional view of the display panel 10 schematically having a first opening 301a, the second opening 301b and a third opening 301c provided in the present disclosure may be a sectional view of A-A of FIG. 1. As shown in FIG. 1, FIG. 1A, FIG. 2 and FIG. 2A, an embodiment of a first aspect of the present disclosure provides a display panel 10. The display panel 10 includes a substrate 100, a pixel defining layer 200, an isolation structure 300, and a light-emitting device 400. The pixel defining layer 200 is disposed on a side of the substrate 100 and includes a pixel defining portion 210 and a pixel opening 220 formed by enclosing the pixel defining portion 210. The isolation structure 300 is disposed on a side of the substrate 100, where an isolation opening 301 is disposed on the isolation structure 300, and the isolation opening 301 communicates with the pixel opening 220. The light-emitting device 400 is at least partially located within the pixel opening 220, where the pixel defining portion 210 exposed from at least part of the isolation opening 301 has a dimple structure 10a disposed on a side of the pixel defining portion 210 facing away from the substrate 100.

In the display panel provided in the embodiments of the present disclosure, the display panel 10 includes the substrate 100, the pixel defining layer 200, the isolation structure 300 and the light-emitting device 400. The pixel defining layer 200 includes the pixel defining portion 210 and the pixel opening 220 formed by enclosing the pixel defining portion 210. The light-emitting device 400 is at least partially located within the pixel opening 220, the isolation structure 300 is disposed on the side of the substrate 100, the isolation opening 301 connecting with the pixel opening 220 is disposed on the isolation structure 300, and the pixel defining layer 200 and the isolation structure 300 may be configured to divide sub-pixels of the display panel 10.

Optionally, the composition, preparation, and the like of the isolation structure 300 are further described in patents CN 118251982A, 202410864269.8, PCT/CN2024/098407, PCT/CN2024/102783, PCT/CN2024/098217, PCT/CN2024/100935, PCT/CN2024/102785, PCT/CN2024/099419, PCT/CN2024/099072 and CN116685174 A, which are incorporated herein by reference.

A plurality of isolation openings 301 are provided, and one isolation opening 301 communicates with at least one pixel opening 220.

Optionally, the isolation structure 300 may be disposed on a side of the pixel defining portion 210 facing away from the substrate 100.

The pixel defining portion 210 exposed from at least part of the isolation opening 301 has the dimple structure 10a disposed on the side of the pixel defining portion 210 facing away from the substrate 100.

In some embodiments of the present disclosure, the substrate 100 may be disposed in various manners, and the substrate 100, for example, may include the base 110 and a driver circuit 150 disposed on the base 110. Optionally, the substrate 100 includes a first insulating layer 120, a second insulating layer 130 and a third insulating layer 140 which are disposed in a stacked manner. Exemplarily, the driver circuit 150 may include a transistor 151, a storage capacitor 152, a drive signal line for connecting various devices, and the like. The transistor 151 includes a semiconductor, a gate 151a and a source/drain 151b. The storage capacitor 152 includes a first plate 152a and a second plate 152b. As an example, the gate 151a and the first plate 152a may be located on a side of the first insulating layer 120 towards the base 110, the second plate 152b may be located between the first insulating layer 120 and the second insulating layer 130, and the source/drain 151b may be located between the second insulating layer 130 and the third insulating layer 140.

In some optional embodiments, the light-emitting device 400 includes a first electrode 410, a light-emitting layer 420, and a second electrode 430 which are laminated in sequence in a direction away from the substrate 100.

Optionally, the light-emitting layer 420 may include a hole injection layer (HIL), a hole transport layer (HTL), a light-emitting structure, an electron injection layer (EIL), and an electron transport layer (ETL).

Optionally, the first electrode 410 and the second electrode 430 may each serve as a pixel electrode of the display panel 10, one of the first electrode 410 and the second electrode 430 may serve as an anode, and the other of the first electrode 410 and the second electrode 430 may serve as a cathode to drive the light-emitting unit to emit light. In the embodiments of the present disclosure, an example in which the first electrode 410 serves as the anode of the display panel 10 and the second electrode 430 serves as the cathode of the display panel 10 will be described.

In some embodiments of the present disclosure, both the isolation structure 300 and the pixel defining layer 200 may be mesh-shaped, a hollow region in the mesh-shaped isolation structure 300 may form the isolation opening 301, and a hollow region in the mesh-shaped pixel defining layer 300 may form the pixel opening 220.

In some optional embodiments, the isolation structure 300 includes a first isolation portion 310 and a second isolation portion 320 located on a side of the first isolation portion 310 facing away from the substrate, and the second isolation portion 320 may be disposed to protrude from the first isolation portion 310 towards the isolation opening 301. For example, the second isolation portion 320 has a first protrusion portion 321 disposed to protrude from the first isolation portion 310 towards the isolation opening 301.

The second isolation portion 320 is disposed to protrude from the first isolation portion 310 towards the isolation opening 301, so that when the light-emitting device 400 of the display panel 10 is prepared, an integral evaporation of a material of the light-emitting device 400 (such as, a material of the light-emitting layer 420 and a material of the second electrode 430) may be directly performed. The second isolation portion 320 may shield at least part of the material for preparing the light-emitting device 400, to partition the material of the light-emitting device 400 between adjacent sub-pixels and form a plurality of light-emitting devices 400 disposed at intervals and located in different isolation openings 301, so that when the light-emitting device 400 of the display panel 10 is prepared, it is not necessary to provide a finer mask, for example, when the material of the light-emitting device 400 is evaporated, it is not necessary to provide a fine metal mask (FMM), and thus the production and manufacturing cost of the display panel 10 can be better reduced.

In some optional embodiments, a material of the isolation structure 300 may include a conductive material, and the second electrode 430 may be connected to the isolation structure 300, so that the second electrodes 430 of adjacent sub-pixels may be electrically connected to each other through the isolation structure 300 to achieve control of the second electrode 430.

In some optional embodiments, the isolation structure 300 further includes a conductive portion 330 disposed on a side of the first isolation portion 310 towards the substrate 100, and the conductive portion 330 is disposed to protrude from the first isolation portion 310 towards the isolation opening 301. For example, the conductive portion 330 has a second protrusion portion 331 disposed to protrude from the first isolation portion 310 towards the isolation opening 301. Optionally, the second electrode 430 is connected to the second protrusion portion 331.

In these optional embodiments, the conductive portion 330 is disposed to protrude from the first isolation portion 310 towards the isolation opening 301, so that the conductive portion 330 may have a larger area thereon to facilitate connection with the second electrode 430, thereby facilitating electrical connection between the second electrode 430 and the isolation structure 300.

Optionally, the second electrode 430 may also be connected to the first isolation portion 310, so that the second electrodes 430 of adjacent sub-pixels may also be electrically connected to each other through the first isolation portion 310.

Optionally, an orthographic projection of the conductive portion 330 on the substrate 100 may also be located within an orthographic projection of the second isolation portion 320 on the substrate 100, so that the second isolation portion 320 may have a relatively sufficient size, to further improve the shielding and partitioning capability of the second isolation portion 320 on the material of the light-emitting device 400.

In some optional embodiments, the isolation opening 301 includes a first opening 301a and a second opening 301b, and the light-emitting device 400 includes a first-type device 401 disposed corresponding to the first opening 301a and a second-type device 402 disposed corresponding to the second opening 301b.

The first-type device 401 disposed corresponding to the first opening 301a may mean that the first-type device 401 may be at least partially located within the first opening 301a. Optionally, the second-type device 402 disposed corresponding to the second opening 301b may mean that the second-type device 402 may be at least partially located within the second opening 301b.

The first-type device 401 and the second-type device 402 have different light-emitting colors to achieve a color display of the display panel 10.

Optionally, the isolation opening 301 may further include a third opening 301c, and the light-emitting device 400 includes a third-type device 403 disposed corresponding to the third opening 301c.

The third-type device 403 disposed corresponding to the third opening 301c may mean that the third-type device 403 may be at least partially located within the third opening 301c.

The first-type device 401, the second-type device 402 and the third-type device 403 have different light-emitting colors to achieve the color display of the display panel 10.

For example, the first-type device 401 is a light-emitting device 400 emitting blue light, the second-type device 402 is a light-emitting device 400 emitting green light, and the third-type device 403 is a light-emitting device 400 emitting red light.

In some embodiments of the present disclosure, a plurality of light-emitting devices 400 of different colors may be prepared separately by the shielding and partitioning effect of the isolation structure 300 on the light-emitting device 400.

In some optional embodiments, the first-type device 401 and the second-type device 402 are prepared separately by using the isolation structure 300.

Specifically, the first opening 301a and the second opening 301b may be firstly prepared simultaneously, and then an integral evaporation of a material of the first-type device 401 may be performed, so that the isolation structure 300 may partition part of the material of the first-type device 401. Then, the material of the first-type device 401 outside the first opening 301a is removed, to form the first-type device 401 disposed corresponding to the first opening 301a. Then, an integral evaporation of a material of the second-type device 402 is performed, so that the isolation structure 300 may partition part of the material of the second-type device 402. Then, a material of the second-type device 402 outside the second opening 301b is removed, to form the second-type device 402 disposed corresponding to the second opening 301b.

Optionally, in step of removing the material of the first-type device 401 outside the first opening 301a, the pixel defining portion 210 exposed from the remaining isolation opening 301 outside the first opening 301a may be etched to a certain extent by using an etching material to form the dimple structure 10a.

In some optional embodiments, the pixel defining portion 210 exposed from the second opening 301b may have the dimple structure 10a disposed on one side of the pixel defining portion 210 facing away from the substrate 100.

In an optional embodiment, in step of removing the material of the first-type device 401 outside the first opening 301a, the pixel defining portion 210 exposed from the second opening 301b may be etched to a certain extent by using the etching material to form the dimple structure 10a.

Optionally, the pixel defining portion 210 exposed from the first opening 301a has a first flat surface 10b disposed on one side of the pixel defining portion 210 facing away from the substrate 100. The pixel defining portion 210 exposed from the first opening 301a does not have the dimple structure disposed on one side of the pixel defining portion 210 facing away from the substrate 100.

Optionally, the pixel defining portion 210 exposed from the third opening 301c has the dimple structure 10a disposed on the side of the pixel defining portion 210 facing away from the substrate 100, or the pixel defining portion 210 exposed from the third opening has the first flat surface 10b disposed on one side of the pixel defining portion 210 facing away from the substrate 100.

When the third opening 301c is prepared simultaneously with the first opening 301a and the second opening 301b, in step of removing the material of the first-type device 401 outside the first opening 301a and step of removing the material of the second-type device 402 outside the second opening 301b, the pixel defining portion 210 exposed from the third opening 301c may be etched to a certain extent by using the etching material to form the dimple structure 10a, so that the pixel defining portion 210 exposed from the third opening 301c may have the dimple structure 10a disposed on one side of the pixel defining portion 210 facing away from the substrate 100.

When the third opening 301c is prepared separately from other isolation openings 301, for example, when the third opening 301c is prepared after the first-type device 401 and the second-type device 402 are prepared, the pixel defining portion 210 exposed from the third opening 301c is not susceptible to the etching material, so that the pixel defining portion 210 exposed from the third opening 301c has the first flat surface 10b disposed on one side of the pixel defining portion 210 facing away from the substrate 100.

In these optional embodiments, the first flat surface 10b refers to a flat surface on the side of the pixel defining portion 210 facing away from the substrate 100. The first flat surface 10b may be relatively flat, and the first flat surface 10b may not have the dimple structure 10a.

In some embodiments of the present disclosure, a film layer located within the dimple structure 10a on the side of the pixel defining portion 210 facing away from the substrate 100 has a concave shape, which may facilitate improving the adhesion between the film layer and an upper film layer and improving the display effect of the display panel. For example, a part of the light-emitting layer 420 is located within the dimple structure 10a, so that the adhesion between the light-emitting layer 420 within the dimple structure 10a and the second electrode 430 located above the light-emitting layer 420 can be improved. Further, the light-emitting layer 420 within the dimple structure 10a has a concave shape, the second electrode 430 above the light-emitting layer 420 also correspondingly has a concave shape, and the second electrode 430 in the concave shape has better adhesion to an encapsulation layer.

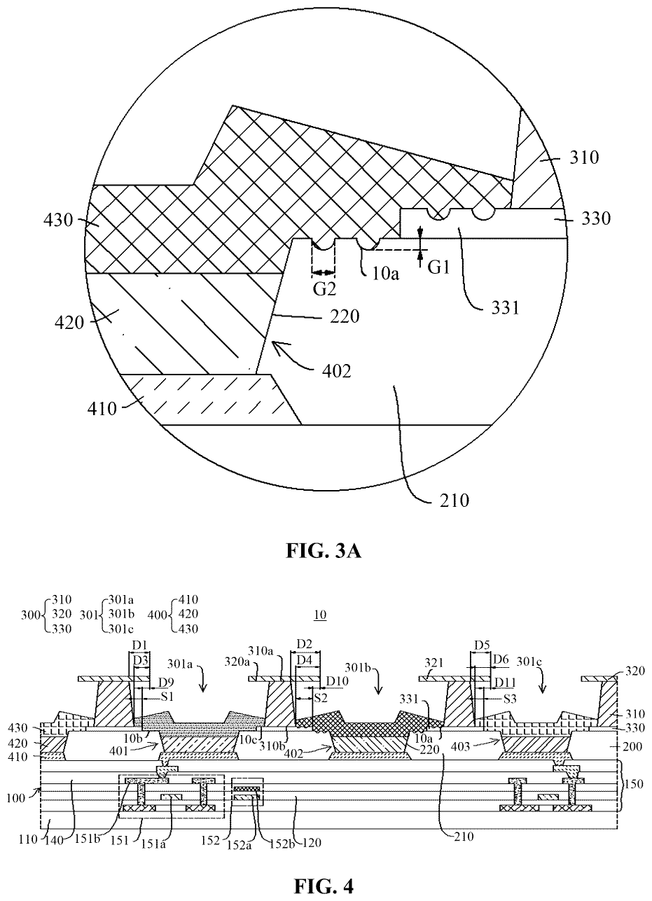

FIG. 3 is a partial sectional view of a display panel 10 according to another embodiment of the present disclosure, and FIG. 3A is a partial enlarged sectional view of a display panel 10 according to another embodiment of the present disclosure. FIG. 3A may be a partial enlarged view of the second opening 301b in FIG. 3.

As shown in FIG. 3, in some optional embodiments, the second protrusion portion 331 of at least part of the conductive portion 330 has the dimple structure 10a disposed on a side of the second protrusion portion 331 facing away from the substrate 100. The dimple structure 10a is disposed on the side of the second protrusion portion 331 of the conductive portion 330 facing away from the substrate 100, so that a connection area between the second electrode 430 and the conductive portion 330 can be improved, and thus the electrical connection effect between the second electrode 430 and the conductive portion 330 can be better improved.

In some optional embodiments, a depth of the dimple structure 10a ranges from 0.3 microns to 0.7 microns, and/or a width of the dimple structure 10a is less than 1.5 microns. For example, each of a depth of the dimple structure 10a of the pixel defining portion 210 and a depth of the dimple structure 10a of the conductive portion 330 ranges from 0.3 microns to 0.7 microns, and/or a depth of the dimple structure 10a of the pixel defining portion 210 and a depth of the dimple structure 10a of the conductive portion 330 are less than 1.5 microns.

Optionally, the depth of the dimple structure 10a may refer to a size of the dimple structure 10a in a thickness direction of the display panel 10. For example, G1 in FIG. 2A and FIG. 3A may indicate the depth of the dimple structure 10a. Optionally, the width of the dimple structure 10a may refer to a size of the dimple structure 10a in a direction from the isolation structure 300 towards the pixel opening 220. For example, G2 in FIG. 2A and FIG. 3A may indicate the width of the dimple structure 10a.

Optionally, the depth of the dimple structure 10a may be 0.3 micrometers, 0.4 micrometers, 0.5 micrometers, 0.6 micrometers, or 0.7 micrometers. Optionally, the width of the dimple structure 10a may be 1.4 micrometers, 1.3 micrometers, 1.2 micrometers, 1.1 micrometers, 1.0 micrometers, 0.9 micrometers, or 0.8 micrometers.

In these optional embodiments, the size of the dimple structure 10a may be properly disposed, so that a water vapor intrusion path can be better adjusted and the connection area between the second electrode 430 and the conductive portion 330 can be better adjusted, thereby better improving the display effect of the display panel 10

In some embodiments of the present disclosure, when the first-type device 401 and the second-type device 402 are separately prepared by using the isolation structure 300, under the influence of the manufacturing process of the display panel 10, the dimple structure 10a may also be only located on the conductive portion 330 within part of the isolation opening 301.

Optionally, in step of removing the material of the first-type device 401 outside the first opening 301a, the second protrusion portion 331 exposed from remaining isolation openings 301 outside the first opening 301a may be etched to a certain extent by using the etching material to form the dimple structure 10a.

In some optional embodiments, the second protrusion portion 331 disposed to protrude from the first isolation portion 310 towards the second opening 301b has the dimple structure 10a disposed on the side of the second protrusion portion 331 facing away from the substrate 100.

In this optional embodiment, in step of removing the material of the first-type device 401 outside the first opening 301a, the second protrusion portion 331 disposed to protrude from the first isolation portion 310 towards the second opening 301b may be etched to a certain extent by using the etching material to form the dimple structure 10a.

Optionally, the second protrusion portion 331 disposed to protrude from the first isolation portion 310 towards the first opening 301a has a second flat surface 10c disposed on the side of the second protrusion portion 331 facing away from the substrate 100.

Optionally, the second protrusion portion 331 disposed to protrude from the first isolation portion 310 towards the third opening 301c has the dimple structure 10a disposed on the side of the second protrusion portion 331 facing away from the substrate 100, or the second protrusion portion 331 disposed to protrude from the first isolation portion 310 towards the third opening 301c has the second flat surface 10c disposed on the side of the second protrusion portion 331 facing away from the substrate 100. The second flat surface 10c refers to a flat surface of a side of the second protrusion portion 331 facing away from the substrate 100.

When the third opening 301c is prepared simultaneously with the first opening 301a and the second opening 301b, in step of removing the material of the first-type device 401 outside the first opening 301a and step of removing the material of the second-type device 402 outside the second opening 301b, the second protrusion portion 331 disposed to be exposed from the third opening 301c and protrude from the first isolation portion 310 towards the third opening 301c may be etched to a certain extent by using the etching material to form the dimple structure 10a, so that the second protrusion portion 331 exposed from the third opening 301c has the dimple structure 10a disposed on the side of the second protrusion portion 331 facing away from the substrate 100.

When the third opening 301c is prepared separately from other isolation openings 301, for example, when the third opening 301c is prepared after the first-type device 401 and the second-type device 402 are prepared, the second protrusion portion 331 disposed to be exposed from the third opening 301c and protrude from the first isolation portion 310 towards the third opening 301c is not susceptible to the etching material, so that the second protrusion portion 331 exposed from the third opening 301c has the second flat surface 10c disposed on the side of the second protrusion portion 331 facing away from the substrate 100.

In these optional embodiments, the second flat surface 10c may be relatively flat, and the second flat surface 10c may not have the dimple structure 10a.

In some optional embodiments, a film layer of the light-emitting device 400 may be partially located within the dimple structure 10a.

For example, the film layer of the light-emitting device 400 may be partially located within the dimple structure 10a of the pixel defining portion 210, and/or the film layer of the light-emitting device 400 may be partially located within the dimple structure 10a of the conductive portion 330.

Optionally, the light-emitting layer 420 is partially located within the dimple structure 10a. For example, the light-emitting layer 420 may extend from the pixel opening 220 to the side of the pixel defining portion 210 facing away from the substrate 100, and the light-emitting layer 420 may be partially located within the dimple structure 10a (not shown) of the pixel defining portion 210.

Optionally, the second electrode 430 is partially located within the dimple structure 10a. For example, the second electrode 430 may extend from the pixel opening 220 to the side of the pixel defining portion 210 facing away from the substrate 100, and the second electrode 430 is partially located within the dimple structure 10a of the pixel defining portion 210. For example, the second electrode 430 may extend to a side of the conductive portion 330 facing away from the substrate 100, and the second electrode 430 is partially located within the dimple structure 10a of the conductive portion 330.

Optionally, one dimple structure or multiple dimple structures 10a are provided. The multiple dimple structures 10a may be disposed at intervals, and/or the multiple dimple structures may be connected to each other. The arrangement of the dimple structures 10a may be disordered, and the dimple structure 10a may have various shapes, which are not specifically limited in the present disclosure.

In some optional embodiments, an orthographic projection of the dimple structure 10a on the substrate 100 is at least partially located within an orthographic projection of the first protrusion portion 321 on the substrate 100. For example, an orthographic projection of the dimple structure 10a of the pixel defining portion 210 on the substrate 100 is at least partially located the orthographic projection of the first protrusion portion 321 on the substrate 100, and/or an orthographic projection of the dimple structure 10a of the conductive portion 330 on the substrate 100 is at least partially located within the orthographic projection of the first protrusion portion 321 on the substrate 100. For example, a part of the orthographic projection of the dimple structure 10a of the pixel defining portion 210 on the substrate 100 is located within the orthographic projection of the first protrusion portion 321 on the substrate 100, and the other part of the orthographic projection of the dimple structure 10a of the pixel defining portion 210 on the substrate 100 is located outside the orthographic projection of the first protrusion portion 321 on the substrate 100. Alternatively, the orthographic projection of the dimple structure 10a of the pixel defining portion 210 on the substrate 100 is located within the orthographic projection of the first protrusion portion 321 on the substrate 100.

In the optional embodiment, due to the shielding and partitioning of the first protrusion portion 321, when the material of the light-emitting device 400 is evaporated, the amount of the material of the light-emitting device 400 dropped below the first protrusion portion 321 is relatively small, so that a thickness of a film layer below the first protrusion portion 321 is relatively thin. Therefore, in step of removing the material of the first-type device 401 outside the first opening 301a and step of removing the material of the second-type device 402 outside the second opening 301b, the material of the light-emitting device 400 below the first protrusion portion 321 is readily etched and removed by using the etching material, and further etches the material of the pixel defining portion 210 and/or the conductive portion 330 below the first protrusion portion 321, so that the dimple structure 10a is easily formed below the first protrusion portion 321.

In the embodiments of the present disclosure, there are many manners to implement that “the second isolation portion 320 is disposed to protrude from the first isolation portion 310 towards the isolation opening 301” and implement that “the conductive portion 330 is disposed to protrude from the first isolation portion 310 towards the isolation opening 301”.

For example, in the manufacturing process of the display panel 10, an etching degree of a material of the first isolation portion 310 may be controlled to implement that “the second isolation portion 320 is disposed to protrude from the first isolation portion 310 towards the isolation opening 301” and implement that “the conductive portion 330 is disposed to protrude from the first isolation portion 310 towards the isolation opening 301”. For another example, in the manufacturing process of the display panel 10, an etching degree of a material of the second isolation portion 320 and an etching degree of a material of the conductive portion 330 may be controlled to implement that “the second isolation portion 320 is disposed to protrude from the first isolation portion 310 towards the isolation opening 301” and implement that “the conductive portion 330 is disposed to protrude from the first isolation portion 310 towards the isolation opening 301”. For another example, in the manufacturing process of the display panel 10, an etching degree of the material of the first isolation portion 310 and an etching degree of the material of the second isolation portion 320, and an etching degree of the material of the first isolation portion 310 and an etching degree of the material of the conductive portion 330 may be controlled to implement that “the second isolation portion 320 is disposed to protrude from the first isolation portion 310 towards the isolation opening 301” and implement that “the conductive portion 330 is disposed to protrude from the first isolation portion 310 towards the isolation opening 301”.

For ease of description, the following embodiments are described by using an example in which “the second isolation portion 320 is disposed to protrude from the first isolation portion 310 towards the isolation opening 301” and “the conductive portion 330 is disposed to protrude from the first isolation portion 310 towards the isolation opening 301” may be implemented by controlling the etching degree of the material of the first isolation portion 310 in the manufacturing process of the display panel 10.

Optionally, the material of the conductive portion 330 may include the conductive material, so that second electrodes 430 of adjacent light-emitting devices 400 may be electrically connected through the conductive portion 330. Optionally, the material of the first isolation portion 310 may also include the conductive material, and at least part of the second electrode 430 may also be connected to the first isolation portion 310, so that second electrodes 430 of adjacent light-emitting devices 400 may also be electrically connected through the first isolation portion 310 to better reduce the resistance of the display panel 10.

Exemplarily, the material of the conductive portion 330 may include molybdenum, the material of the first isolation portion 310 may include aluminum, and the material of the second isolation portion 320 may include titanium, so that the first isolation portion 310 and the second isolation portion 320 may have a relatively large etching selection ratio therebetween, and the first isolation portion 310 and the conductive portion 330 may have a relatively large etching selection ratio therebetween. In this way, when the etching process is performed, an etching rate of the etching material for the first isolation portion 310 may be greater than an etching rate of the etching material for the second isolation portion 320, and an etching rate of the etching material for the first isolation portion 310 may be greater than an etching rate of the etching material for the conductive portion 330, to implement that “the second isolation portion 320 is disposed to protrude from the first isolation portion 310 towards the isolation opening 301” and “the conductive portion 330 is disposed to protrude from the first isolation portion 310 towards the isolation opening 301”.

FIG. 4 is a partial sectional view of a display panel 10 according to still another embodiment of the present disclosure.

As shown in FIG. 4, in some optional embodiments, a length of a protrusion of the second isolation portion 320 towards the first opening 301a with respect to the first isolation portion 310 is less than a length of a protrusion of the second isolation portion 320 towards the second opening 301b with respect to the first isolation portion 310.

Optionally, a side of the first isolation portion 310 facing away from the substrate 100 has a first surface 310a, and a side of the second isolation portion 320 towards the substrate 100 has a second surface 320a. A first spacing D1 exists between an orthographic projection of an edge of the first opening 301a corresponding to the first surface 310a on the substrate 100 and an orthographic projection of an edge of the first opening 301a corresponding to the second surface 320a on the substrate 100, a second spacing D2 exists between an orthographic projection of an edge of the second opening 301b corresponding to the first surface 310a on the substrate 100 and an orthographic projection of an edge of the second opening 301b corresponding to the second surface 320a on the substrate 100, and the first spacing D1 is less than the second spacing D2 to achieve implementing that the length of the protrusion of the second isolation portion 320 towards the first opening 301a with respect to the first isolation portion 310 is less than the length of the protrusion of the second isolation portion 320 towards the second opening 301b with respect to the first isolation portion 310.

Optionally, a side of the first isolation portion 310 close to the substrate 100 has a third surface 310b, a third spacing D3 exists between an orthographic projection of an edge of the first opening 301a corresponding to the third surface 310b on the substrate 100 and the orthographic projection of the edge of the first opening 301a corresponding to the second surface 320a on the substrate 100, a fourth spacing D4 exists between an orthographic projection of an edge of the second opening 301b corresponding to the third surface 310b on the substrate 100 and an orthographic projection of the edge of the second opening 301b corresponding to the second surface 320a on the substrate 100, and the third spacing D3 is less than the fourth spacing D4, so that the length of the protrusion of the second isolation portion 320 towards the first opening 301a with respect to the entirety of the first isolation portion 310 is less than a length of a protrusion of the second isolation portion 320 towards the second opening 301b with respect to the entirety of the first isolation portion 310.

In these optional embodiments, the length of the protrusion of the second isolation portion 320 towards the first opening 301a with respect to the first isolation portion 310 is disposed to be less than the length of the protrusion of the second isolation portion 320 towards the second opening 301b with respect to the first isolation portion 310, so that the isolation structure 300 on a peripheral side of the second opening 301b can have a better shielding and partitioning effect on the material of the light-emitting device 400 to achieve the preparation of the second-type device 402.

In some optional embodiments, a length of a protrusion of the conductive portion 330 towards the first opening 301a with respect to the first isolation portion 310 is less than a length of a protrusion of the conductive portion 330 towards the second opening 301b with respect to the first isolation portion 310.

Optionally, S1 in the drawings may indicate the length of the protrusion of the conductive portion 330 towards the first opening 301a with respect to the first isolation portion 310, and S2 in the drawings may indicate the length of the protrusion of the conductive portion 330 towards the second opening 301b with respect to the first isolation portion 310.

Optionally, the length of the protrusion of the conductive portion 330 towards the second opening 301b with respect to the first isolation portion 310 is greater than the length of the protrusion of the conductive portion 330 towards the first opening 301a with respect to the first isolation portion 310 and is not larger than 3 times the length of the protrusion of the conductive portion 330 towards the first opening 301a with respect to the first isolation portion 310.

Optionally, a length of a protrusion of the conductive portion towards the first opening 301a with respect to the first isolation portion 310 ranges from 0.05 micrometers to 0.4 micrometers. For example, the length of the protrusion of the conductive portion towards the first opening 301a with respect to the first isolation portion 310 may be 0.05 micrometers, 0.1 micrometers, 0.15 micrometers, 0.2 micrometers, 0.25 micrometers, 0.3 micrometers, 0.35 micrometers, or 0.4 micrometers.

In these optional embodiments, the length of the protrusion of the conductive portion 330 towards the first opening 301a with respect to the first isolation portion 310 is disposed to be less than the length of the protrusion of the conductive portion 330 towards the second opening 301b with respect to the first isolation portion 310, so that a relatively large lap area may exist between the second-type device 402 and the conductive portion 330 on a peripheral side of the second opening 301b, and so that in the manufacturing process of the display panel 10, the material of the conductive portion 330 within the second opening 301b is not easily damaged by etching, and the stability of electrical connection between the second-type device 402 and the conductive portion 330 on the peripheral side of the second opening 301b can be better improved, whereby the operation reliability of the display panel 10 can be better improved.

In some embodiments of the present disclosure, an etching degree of the etching material on the first isolation portion 310 of a peripheral side of the first opening 301a may be adjusted to be less than an etching degree of the etching material on the first isolation portion 310 of the peripheral side of the second opening 301b, so that the length of the protrusion of the second isolation portion 320 towards the first opening 301a with respect to the first isolation portion 310 is less than the length of the protrusion of the second isolation portion 320 towards the second opening 301b with respect to the first isolation portion 310, and the length of the protrusion of the conductive portion 330 towards the first opening 301a with respect to the first isolation portion 310 is less than the length of the protrusion of the conductive portion 330 towards the second opening 301b with respect to the first isolation portion 310.

Therefore, a larger connection area is allowed between the second electrode 430 and the conductive portion 330 on the peripheral side of the second opening 301b. Due to the shielding effect of a relative long second isolation portion 320 on the peripheral side of the second opening 301b, a relatively small connection area exists between the second electrode 430 and the first isolation portion 310 on the peripheral side of the second opening 301b. When the material of the conductive portion 330 includes molybdenum and the material of the first isolation portion 310 includes aluminum, the conductive portion 330 is less prone to oxidation than the first isolation portion 310, so that the second electrode 430 may be more connected to the conductive portion 330 which is unlikely to be oxidized, whereby the overall reliability of the electrical connection between the second electrode 430 and the isolation structure 300 can be better improved.

In some embodiments of the present disclosure, when the first-type device 401 and the second-type device 402 are separately prepared by using the isolation structure 300, after a material of the first-type device 401 outside the first opening 301a is removed, the second opening 301b may be washed by using an etching solution to remove impurities in the second opening 301b. For example, the second opening 301b may be washed by using the etching material to remove impurities in the second opening 301b. In a process of washing the second opening 301b, the first isolation portion 310 is easily etched by using the etching material, so that the first isolation portion 310 on the peripheral side of the second opening 301b is etched by using the etching material, and the conductive portion 330 on the peripheral side of the second opening 301b is not etched by using the etching material, thereby increasing a length of a protrusion of the conductive portion 330 on the peripheral side of the second opening 301b with respect to the first isolation portion 310. In this embodiment, the first isolation portion 310 on the peripheral side of the second opening 301b is etched by using the etching material, whereby the length of the protrusion of the second isolation portion 320 towards the first opening 301a with respect to the first isolation portion 310 is less than the length of the protrusion of the second isolation portion 320 towards the second opening 301b with respect to the first isolation portion 310, and the length of the protrusion of the conductive portion 330 towards the first opening 301a with respect to the first isolation portion 310 is less than the length of the protrusion of the conductive portion 330 towards the second opening 301b with respect to the first isolation portion 310.

In some optional embodiments, a length of a protrusion of the second isolation portion 320 towards the third opening 301c with respect to the first isolation portion 310 is not less than the length of the protrusion of the second isolation portion 320 towards the first opening 301a with respect to the first isolation portion 310, and/or the length of the protrusion of the second isolation portion 320 towards the third opening 301c with respect to the first isolation portion 310 is not greater than the length of the protrusion of the second isolation portion 320 towards the second opening 301b with respect to the first isolation portion 310.

For example, the length of the protrusion of the second isolation portion 320 towards the third opening 301c with respect to the first isolation portion 310 may be greater than or equal to the length of the protrusion of the second isolation portion 320 towards the first opening 301a with respect to the first isolation portion 310. For example, the length of the protrusion of the second isolation portion 320 towards the third opening 301c with respect to the first isolation portion 310 is less than or equal to the length of the protrusion of the second isolation portion 320 towards the second opening 301b with respect to the first isolation portion 310.

Optionally, a fifth spacing D5 exists between an orthographic projection of an edge of the third opening 301c corresponding to the first surface 310a on the substrate 100 and an orthographic projection of an edge of the third opening 301c corresponding to the second surface 320a on the substrate 100.

The fifth spacing D5 may be not less than the first spacing D1, so that the length of the protrusion of the second isolation portion 320 towards the third opening 301c with respect to the first isolation portion 310 is not less than the length of the protrusion of the second isolation portion 320 towards the first opening 301a with respect to the first isolation portion 310. The fifth spacing D5 may be not greater than the second spacing D2, so that the length of the protrusion of the second isolation portion 320 towards the third opening 301c with respect to the first isolation portion 310 is not greater than the length of the protrusion of the second isolation portion 320 towards the second opening 301b with respect to the first isolation portion 310.

Optionally, a sixth spacing D6 exists between an orthographic projection of an edge of the third opening 301c corresponding to the third surface 310b on the substrate 100 and the orthographic projection of the edge of the third opening 301c corresponding to the second surface 320a on the substrate 100.

The sixth spacing D6 may be not less than the third spacing D3, so that a length of a protrusion of the second isolation portion 320 towards the third opening 301c with respect to the entirety of the first isolation portion 310 is not less than the length of the protrusion of the second isolation portion 320 towards the first opening 301a with respect to the entirety of the first isolation portion 310. The sixth spacing D6 may be not greater than the fourth spacing D4, so that the length of the protrusion of the second isolation portion 320 towards the third opening 301c with respect to the entirety of the first isolation portion 310 is not greater than the length of the protrusion of the second isolation portion 320 towards the second opening 301b with respect to the entirety of the first isolation portion 310.

In these optional embodiments, the length of the protrusion of the second isolation portion 320 towards the third opening 301c with respect to the first isolation portion 310 is disposed to be not less than the length of the protrusion of the second isolation portion 320 towards the first opening 301a with respect to the first isolation portion 310, and the length of the protrusion of the second isolation portion 320 towards the third opening 301c with respect to the first isolation portion 310 is disposed to be not greater than the length of the protrusion of the second isolation portion 320 towards the second opening 301b with respect to the first isolation portion 310, so that the shielding and partitioning capability of the isolation structure 300 on a peripheral side of the third opening 301c on the material of the light-emitting device 400 may be between the shielding and partitioning capability of the isolation structure 300 on the peripheral side of the first opening 301a and the shielding and partitioning capability of the isolation structure 300 on the peripheral side of the second opening 301b to achieve the preparation of the third-type device 403.

In some optional embodiments, a length of a protrusion of the conductive portion 330 towards the third opening 301c with respect to the first isolation portion 310 is not less than the length of the protrusion of the conductive portion 330 towards the first opening 301a with respect to the first isolation portion 310, and/or a length of a protrusion of the conductive portion 330 towards the third opening 301c with respect to the first isolation portion 310 is not greater than the length of the protrusion of the conductive portion 330 towards the second opening 301b with respect to the first isolation portion 310.

For example, a length of a protrusion of the conductive portion 330 towards the third opening 301c with respect to the first isolation portion 310 is greater than or equal to the length of the protrusion of the conductive portion 330 towards the first opening 301a with respect to the first isolation portion 310. For example, the length of the protrusion of the conductive portion 330 towards the third opening 301c with respect to the first isolation portion 310 is less than or equal to the length of the protrusion of the conductive portion 330 towards the second opening 301b with respect to the first isolation portion 310.

Optionally, S3 in the drawings may denote the length of the protrusion of the conductive portion 330 towards the third opening 301c with respect to the first isolation portion 310.

Optionally, the length of the protrusion of the conductive portion 330 towards the third opening 301c with respect to the first isolation portion 310 ranges from 0.05 micrometers to 0.4 micrometers. For example, the length of the protrusion of the conductive portion towards the third opening 301c with respect to the first isolation portion 310 may be 0.05 micrometers, 0.1 micrometers, 0.15 micrometers, 0.2 micrometers, 0.25 micrometers, 0.3 micrometers, 0.35 micrometers or 0.4 micrometers.

In these optional embodiments, the length of the protrusion of the conductive portion 330 towards the third opening 301c with respect to the first isolation portion 310 is disposed to be not less than the length of the protrusion of the conductive portion 330 towards the first opening 301a with respect to the first isolation portion 310, and the length of the protrusion of the conductive portion 330 towards the third opening 301c with respect to the first isolation portion 310 is disposed to be not greater than the length of the protrusion of the conductive portion 330 towards the second opening 301b with respect to the first isolation portion 310, so that a relatively moderate lap area may exist between the third-type device 403 and the conductive portion 330 on a peripheral side of the third opening 301c, and so that in the manufacturing process of the display panel 10, the material of the conductive portion 330 within the third opening 301c is not easily damaged by etching, and the stability of electrical connection between the third-type device 403 and the conductive portion 330 on the peripheral side of the third opening 301c can be better improved, whereby the operation reliability of the display panel 10 can be better improved.

FIG. 5 is a partial sectional view of a display panel 10 according to another embodiment of the present disclosure.

As shown in FIG. 5, in some optional embodiments, the isolation opening 301 further includes a fourth opening 301d, and the light-emitting device includes a fourth-type device 404 disposed corresponding to the fourth opening 301d.

Optionally, the fourth-type device 404 disposed corresponding to the fourth opening 301d may refer to that the fourth-type device 404 may be at least partially located within the fourth opening 301d.

Optionally, the first-type device 401, the second-type device 402, the third-type device 403 and the fourth-type device 404 have different light-emitting colors to achieve the color display of the display panel 10.

Optionally, the fourth-type device 404 is a light-emitting device 400 emitting white light.

In some optional embodiments, the pixel defining portion 210 exposed from the fourth opening 301d has the dimple structure 10a disposed on the side of the pixel defining portion 210 facing away from the substrate 100, or the pixel defining portion 210 exposed from the fourth opening 301d has the first flat surface 10b disposed on the side of the pixel defining portion 210 facing away from the substrate 100.

When the fourth opening 301d is prepared simultaneously with the first opening 301a and the second opening 301b, in step of removing the material of the first-type device 401 outside the first opening 301a and step of removing the material of the second-type device 402 outside the second opening 301b, the pixel defining portion 210 exposed from the fourth opening 301d may be etched to a certain extent by using the etching material to form the dimple structure 10a, so that the pixel defining portion 210 exposed from the fourth opening 301d may have the dimple structure 10a disposed on the side of the pixel defining portion 210 facing away from the substrate 100.

Alternatively, when the fourth opening 301d and the third opening 301c are prepared simultaneously, the third-type device 403 may be fabricated and then the fourth-type device 404 is fabricated by using a method same as or similar to the method for fabricating the first-type device 401 and the second-type device 402. In step of removing the material of the third-type device 403 outside the third opening 301c, the pixel defining portion 210 exposed from the fourth opening 301d may be etched to a certain extent by using the etching material to form the dimple structure 10a, so that the pixel defining portion 210 exposed from the fourth opening 301d may have the dimple structure 10a disposed on the side of the pixel defining portion 210 facing away from the substrate 100.

When the fourth opening 301d is prepared separately from other isolation openings 301, for example, when the fourth opening 301d is prepared after the first-type device 401, the second-type device 402 and the third-type device 403 are prepared, the pixel defining portion 210 exposed from the fourth opening 301d is not susceptible to the etching material, so that the pixel defining portion 210 exposed from the fourth opening 301d has the first flat surface 10b disposed on the side of the pixel defining portion 210 facing away from the substrate 100.

In some optional embodiments, the second protrusion portion 331 disposed to protrude from the first isolation portion 310 towards the fourth opening 301d has the dimple structure 10a disposed on the side of the second protrusion portion 331 facing away from the substrate 100, or the second protrusion portion 331 disposed to protrude from the first isolation portion 310 towards the fourth opening 301d has the second flat surface 10c disposed on the side of the second protrusion portion 331 facing away from the substrate 100.

When the fourth opening 301d is prepared simultaneously with the first opening 301a and the second opening 301b, in step of removing the material of the first-type device 401 outside the first opening 301a and step of removing the material of the second-type device 402 outside the second opening 301b, the second protrusion portion 331 exposed from the fourth opening 301d may be etched to a certain extent by using the etching material to form the dimple structure 10a, so that the second protrusion portion 331 exposed from the fourth opening 301d may have the dimple structure 10a disposed on the side of the second protrusion portion 331 facing away from the substrate 100.

Alternatively, when the fourth opening 301d and the third opening 301c are prepared simultaneously, the third-type device 403 may be fabricated and then the fourth-type device 404 is fabricated by using a method same as or similar to the method for fabricating the first-type device 401 and the second-type device 402. In step of removing the material of the third-type device 403 outside the third opening 301c, the second protrusion portion 331 exposed from the fourth opening 301d may be etched to a certain extent by using the etching material to form the dimple structure 10a, so that the second protrusion portion 331 exposed from the fourth opening 301d may have the dimple structure 10a disposed on the side of the second protrusion portion 331 facing away from the substrate 100.

When the fourth opening 301d is prepared separately from other isolation openings 301, for example, when the fourth opening 301d is prepared after the first-type device 401, the second-type device 402 and the third-type device 403 are prepared, the second protrusion portion 331 exposed from the fourth opening 301d is not susceptible to the etching material, so that the second protrusion portion 331 exposed from the fourth opening 301d has the first flat surface 10b disposed on the side of the second protrusion portion 331 facing away from the substrate 100.

In some optional embodiments, a length of a protrusion of the second isolation portion 320 towards the fourth opening 301d with respect to the first isolation portion 310 is greater than or equal to the length of the protrusion of the second isolation portion 320 towards the third opening 301c with respect to the first isolation portion 310.

Optionally, a seventh spacing D7 exists between an orthographic projection of an edge of the fourth opening 301d corresponding to the first surface 310a on the substrate 100 and an orthographic projection of an edge of the fourth opening 301d corresponding to the second surface 320a on the substrate 100, the seventh spacing D7 is greater than or equal to the fifth spacing D5 to achieve implementing that the length of the protrusion of the second isolation portion 320 towards the fourth opening 301d with respect to the first isolation portion 310 is greater than or equal to the length of the protrusion of the second isolation portion 320 towards the third opening 301c with respect to the first isolation portion 310.

Optionally, the seventh spacing D7 is not less than the first spacing D1, and/or the seventh spacing D7 is not greater than the second distance D2, so that the length of the protrusion of the second isolation portion 320 towards the fourth opening 301d with respect to the first isolation portion 310 may be between the length of the protrusion of the second isolation portion 320 towards the first opening 301a with respect to the first isolation portion 310 and the length of the protrusion of the second isolation portion 320 towards the second opening 301b with respect to the first isolation portion 310.

Optionally, an eighth spacing D8 exists between an orthographic projection of an edge of the fourth opening 301d corresponding to the third surface 310b on the substrate 100 and the orthographic projection of the edge of the fourth opening 301d corresponding to the second surface 320a on the substrate 100, the eighth spacing is not less than the third spacing to achieve implementing that a length of a protrusion of the second isolation portion 320 towards the fourth opening 301d with respect to the entirety of the first isolation portion 310 is greater than or equal to the length of the protrusion of the second isolation portion 320 towards the third opening 301c with respect to the entirety of the first isolation portion 310.

Optionally, the eighth spacing D8 is not less than the third spacing D3, and/or the eighth spacing D8 is not greater than the fourth spacing D4, so that the length of the protrusion of the second isolation portion 320 towards the fourth opening 301d with respect to the entirety of the first isolation portion 310 may be between the length of the protrusion of the second isolation portion 320 towards the first opening 301a with respect to the entirety of the first isolation portion 310 and the length of the protrusion of the second isolation portion 320 towards the second opening 301b with respect to the entirety of the first isolation portion 310.

In these optional embodiments, the length of the protrusion of the second isolation portion 320 towards the fourth opening 301d with respect to the first isolation portion 310 is disposed to be greater than or equal to the length of the protrusion of the second isolation portion 320 towards the third opening 301c with respect to the first isolation portion 310, so that the isolation structure 300 on a peripheral side of the fourth opening 301d can have a better shielding and partitioning effect on the material of the light-emitting device 400 to achieve the preparation of the fourth-type device 404.

In some optional embodiments, a length of a protrusion of the conductive portion 330 towards the fourth opening 301d with respect to the first isolation portion 310 is greater than or equal to the length of the protrusion of the conductive portion 330 towards the third opening 301c with respect to the first isolation portion 310.

Optionally, S4 in the drawings may denote the length of the protrusion of the conductive portion 330 towards the fourth opening 301d with respect to the first isolation portion 310.

In these optional embodiments, the length of the protrusion of the conductive portion 330 towards the fourth opening 301d with respect to the first isolation portion 310 is disposed to be greater than or equal to the length of the protrusion of the conductive portion 330 towards the third opening 301c with respect to the first isolation portion 310, so that a relatively large lap area may exist between the fourth-type device 404 and the conductive portion 330 on a peripheral side of the fourth opening 301d, and so that in the manufacturing process of the display panel 10, the material of the conductive portion 330 within the fourth opening 301d is not easily damaged by etching, and the stability of electrical connection between the fourth-type device 404 and the conductive portion 330 on the peripheral side of the fourth opening 301d can be better improved, whereby the operation reliability of the display panel 10 can be better improved.

As shown in FIG. 5, in some optional embodiments, a ninth spacing D9 exists between an orthographic projection of an edge of the second isolation portion 320 on a side facing the first opening 301a on the substrate 100 and an orthographic projection of an edge of the conductive portion 330 on a side facing the first opening 301a on the substrate 100, a tenth spacing D10 exists between an orthographic projection of an edge of the second isolation portion 320 on a side facing the second opening 301b on the substrate 100 and an orthographic projection of an edge of the conductive portion 330 on a side facing the second opening 301b on the substrate 100, and the ninth spacing D9 may be equal to the tenth spacing D10.

Optionally, the ninth spacing D9 and the tenth spacing D10 ranges from 0.1 micrometers to 0.6 micrometers. For example, values of the ninth spacing D9 and the tenth spacing D10 may be 0.1 micrometers, 0.2 micrometers, 0.3 micrometers, 0.4 micrometers, 0.5 micrometers, or 0.6 micrometers.

Optionally, an eleventh interval D11 exists between an orthographic projection of an edge of the second isolation portion 320 on a side facing the third opening 301c on the substrate 100 and an orthographic projection of an edge of the conductive portion 330 on a side facing the third opening 301c on the substrate 100, and the ninth spacing D9, the tenth spacing D10 and the eleventh interval D11 are equal to each other.

Optionally, the eleventh spacing D11 ranges from 0.1 micron to 0.6 micron. For example, the eleventh spacing D11 may be 0.1 micrometers, 0.2 micrometers, 0.3 micrometers, 0.4 micrometers, 0.5 micrometers, or 0.6 micrometers.

Optionally, the orthographic projection of the second isolation portion 320 towards the edge of the fourth opening 301d side on the substrate 100 and the orthographic projection of the conductive portion 330 towards the edge of the fourth opening 301d side on the substrate 100 have a twelfth spacing D12, and the ninth spacing D9, the tenth spacing D10, and the eleventh spacing D11 are equal to the twelfth spacing D12.

Optionally, the twelfth spacing D12 ranges from 0.1 micron to 0.6 micron. For example, the twelfth spacing D12 may be 0.1 micrometers, 0.2 micrometers, 0.3 micrometers, 0.4 micrometers, 0.5 micrometers, or 0.6 micrometers.

In these optional embodiments, the etching degree of the material of the first isolation portion 310 may be controlled to implement that “the second isolation portion 320 is disposed to protrude from the first isolation portion 310 towards the isolation opening 301” and implement that “the conductive portion 330 is disposed to protrude from the first isolation portion 310 towards the isolation opening 301”. Since the etching degree of the first isolation portion 310 is adjusted, a relative position relationship between the first isolation portion 310 and the second isolation portion 320 in each isolation opening 301 does not change excessively, so that the twelfth spacing D12, the ninth spacing D9, the tenth spacing D10, and the eleventh spacing D11 may be equal to each other.

FIG. 6 is a partial sectional view of a display panel 10 according to another embodiment of the present disclosure.

As shown in FIG. 6, in some optional embodiments, the display panel 10 further includes an encapsulation layer 500 disposed on a side of the light-emitting device 400 and the isolation structure 300 which face away from the substrate 100, and the encapsulation layer 500 may be configured to encapsulate the light-emitting device 400.

Optionally, the encapsulation layer 500 may include a first encapsulation layer 510 disposed on a side of the light-emitting device 400 and the isolation structure 300 which face away from the substrate 100. The first encapsulation layer 510 may include encapsulation units 511 disposed corresponding to the light-emitting devices 400, and each of the encapsulation units 511 may be configured to perform a relatively independent encapsulation on each light-emitting device 400 to better improve the encapsulation effect of the display panel 10.

Optionally, a material of the first encapsulation layer 510 may include an inorganic material, so that the first encapsulation layer 510 can better limit the impact of water vapor on the light-emitting device 400.

Optionally, the first encapsulation layer 510 may be prepared by using a chemical vapor deposition (CVD) process.

Optionally, the encapsulation layer 500 may further include a second encapsulation layer 520 disposed on a side of the first encapsulation layer 510 facing away from the substrate 100, and the second encapsulation layer 520 may also encapsulate the display panel 10, to further improve the encapsulation effect of the display panel 10.

Optionally, a material of the second encapsulation layer 520 includes an organic material, so that when the second encapsulation layer 520 is prepared, the material of the second encapsulation layer 520 may have better fluidity, and a side surface of the formed second encapsulation layer 520 facing away from the substrate 100 may have better flatness to achieve arrangement of subsequent components.

Optionally, the second encapsulation layer 520 may be prepared by using an inkjet printing (IJP) technology process.

Optionally, the encapsulation layer 500 may further include a third encapsulation layer 530 disposed on a side of the second encapsulation layer 520 facing away from the substrate 100, and the third encapsulation layer 530 may also encapsulate the display panel 10, to further improve the encapsulation effect of the display panel 10.

Optionally, a material of the third encapsulation layer 530 includes an inorganic material. Optionally, the third encapsulation layer 530 may be prepared by using the CVD.

FIG. 7 is a partial sectional view of a display panel 10 according to another embodiment of the present disclosure.

Referring to FIG. 7 in conjunction with FIG. 1 to FIG. 6, an embodiment of the first aspect of the present disclosure further provides a display panel 10. The display panel 10 includes a substrate 100, an isolation structure 300, and a light-emitting device 400. The isolation structure 300 is disposed on a side of the substrate 100, an isolation opening 301 is disposed on the isolation structure 300, the isolation structure 300 includes a first isolation portion 310 and a conductive portion 330 disposed on a side of the first isolation portion 310 towards the substrate 100, and the conductive portion 330 has a second protrusion portion 331 disposed to protrude from the first isolation portion 310 that protrudes towards the isolation opening 301. The light-emitting device 400 is at least partially located within the isolation opening 301, where the second protrusion portion 331 of at least part of the conductive portion 330 has a dimple structure 10a disposed on the side of the second protrusion portion 331 facing away from the substrate 100.

In the display panel further provided in the embodiments of the present disclosure, the display panel 10 includes the substrate 100, the isolation structure 300, and the light-emitting device 400. The isolation structure 300 is disposed on the side of the substrate 100, the isolation opening 301 is disposed on the isolation structure 300, the light-emitting device 400 is at least partially located within the isolation opening 301, and the isolation structure 300 may be configured to divide sub-pixels of the display panel 10.

The isolation structure 300 includes a first isolation portion 310 and a conductive portion 330 disposed on a side of the first isolation portion 310 towards the substrate 100. The second protrusion portion 331 of at least part of the conductive portion 330 has the dimple structure 10a disposed on the side of the second protrusion portion 331 facing away from the substrate 100, so that the display effect of the display panel can be improved.

Optionally, the display panel 10 further provided in the embodiments of the first aspect of the present disclosure may be the display panel 10 in any one of the foregoing embodiments, so that the display panel 10 further provided in the embodiments of the present disclosure may have the structure and beneficial effects of the display panel 10 in any one of the foregoing embodiments, and the details are not repeated in the present disclosure.

For example, the light-emitting device 400 may be the light-emitting device 400 in any one of the foregoing embodiments, and the light-emitting device 400 may include the first-type device 401, the second-type device 402, the third-type device 403 and the fourth-type device 404 in any one of the embodiments. The light-emitting device 400 includes a first electrode 410, a light-emitting layer 420, and a second electrode 430 which are laminated in sequence in a direction away from the substrate 100. The second electrode 430 may be connected to the conductive portion 330, so that second electrodes 430 of adjacent sub-pixels may be electrically connected through the isolation structure 300 to achieve the control of the second electrode 430. The second protrusion portion 331 of at least part of the conductive portion 330 is disposed to have the dimple structure 10a disposed on the side of the second protrusion portion 331 facing away from the substrate 100, so that the connection area between the second electrode 430 and the conductive portion 330 can be increased, whereby the electrical connection effect between the second electrode 430 and the conductive portion 330 can be better improved.

For example, the isolation structure 300 may be the isolation structure 300 in any one of the foregoing embodiments, and the isolation opening 301 in any one of the foregoing embodiments may be formed by enclosing the isolation structure 300. Specifically, the isolation opening 301 may include the first opening 301a, the second opening 301b, the third opening 301c and the fourth opening 301d in any one of the foregoing embodiments. The isolation structure 300 may include the conductive portion 330, the first isolation portion 310 and the second isolation portion 320 in any one of the foregoing embodiments, where the relative position relationship and the size relationship among the conductive portion 330, the first isolation portion 310 and the second isolation portion 320 may be set with reference to any one of the foregoing embodiments.

Optionally, the display panel 10 further provided in the embodiments of the first aspect of the present disclosure may further include the pixel defining layer 200 in any one of the foregoing embodiments, and the pixel defining layer 200 may include the pixel defining portion 210 and the pixel opening 220 in any one of the foregoing embodiments. A side of at least part of the pixel defining portion 210 facing away from the substrate 100 may have the dimple structure 10a.

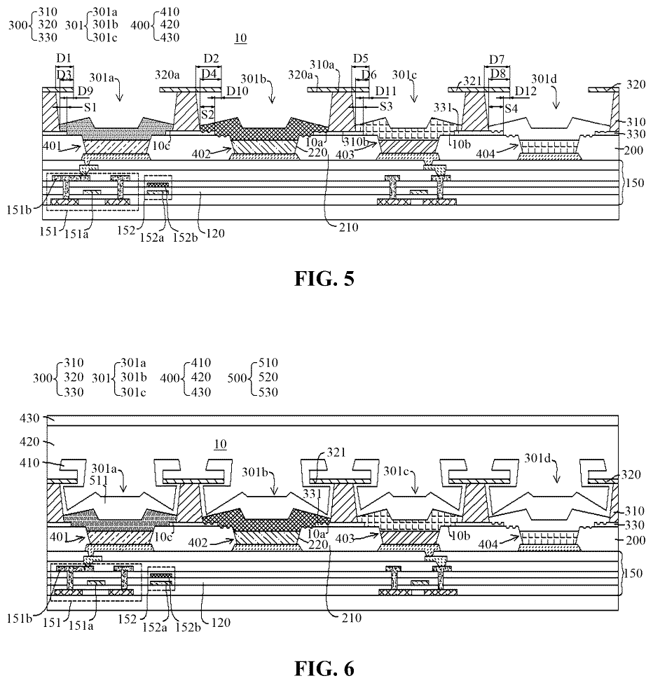

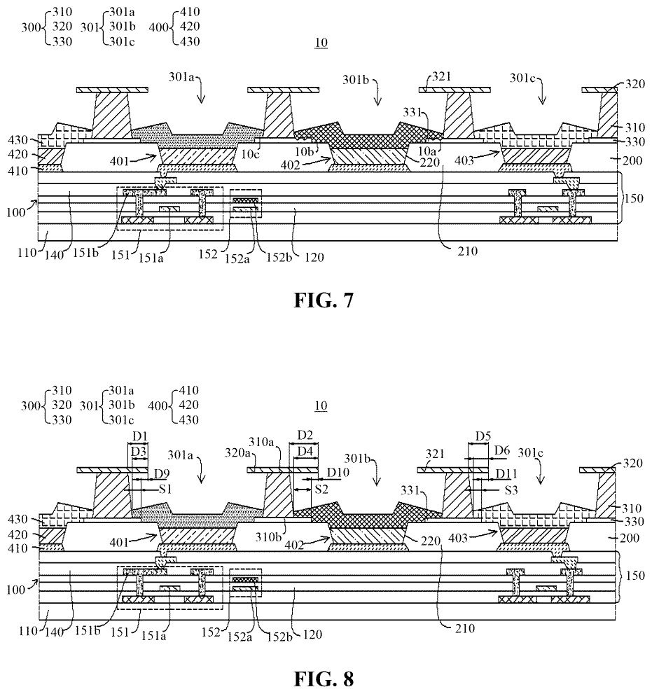

FIG. 8 is a partial sectional view of a display panel 10 according to another embodiment of the present disclosure.

Referring to FIG. 8 in conjunction with FIG. 1 to FIG. 7, an embodiment of the first aspect of the present disclosure further provides a display panel 10. The display panel 10 includes a substrate 100, an isolation structure 300 and a light-emitting device 400. The isolation structure 300 is disposed on a side of the substrate 100, an isolation opening 301 is disposed on the isolation structure 300, the isolation opening includes a first opening 301a, a second opening 301b and a third opening 301c, the isolation structure 300 includes a first isolation portion 310 and a second isolation portion 320 located on a side of the first isolation portion 310 facing away from the substrate 100, and the second isolation portion 320 is disposed to protrude from the first isolation portion 310 towards the isolation opening 301. The light-emitting device 400 includes a first-type device 401 disposed corresponding to the first opening 301a, a second-type device 402 disposed corresponding to the second opening 301b, and a third-type device 403 disposed corresponding to the third opening 301c. A side of the first isolation portion 310 facing away from the substrate 100 has a first surface 310a, a side of the second isolation portion 320 towards the substrate 100 has a second surface 320a, a first spacing D1 exists between an orthographic projection of an edge of the first opening 301a corresponding to the first surface 310a on the substrate 100 and an orthographic projection of an edge of the first opening 301a corresponding to the second surface 320a on the substrate 100, a second spacing D2 exists between an orthographic projection of an edge of the second opening 301b corresponding to the first surface 310a on the substrate 100 and an orthographic projection of an edge of the second opening 301b corresponding to the second surface 320a on the substrate 100, and the first spacing is less than the second spacing, and a fifth spacing D5 exists between an orthographic projection of an edge of the third opening 301c corresponding to the first surface 310a on the substrate 100 and an orthographic projection of an edge of the third opening 301c corresponding to the second surface 320a on the substrate 100, where the first spacing D1 is less than the second spacing D2, and the fifth spacing D5 is equal to the first spacing D1. And/or, a side of the first isolation portion 310 close to the substrate 100 has a third surface 310b, a third spacing D3 exists between an orthographic projection of an edge of the first opening 301a corresponding to the third surface 310b on the substrate 100 and the orthographic projection of the edge of the first opening 301a corresponding to the second surface 320a on the substrate 100, a fourth spacing D4 exists between an orthographic projection of an edge of the second opening 301b corresponding to the third surface 310b on the substrate 100 and an orthographic projection of the edge of the second opening 301b corresponding to the second surface 320a on the substrate 100, and a sixth spacing D6 exists between an orthographic projection of an edge of the third opening 301c corresponding to the third surface 310b on the substrate 100 and the orthographic projection of the edge of the third opening 301c corresponding to the second surface 320a on the substrate 100, where the third spacing D3 is less than the fourth spacing D4, and the sixth spacing D6 is equal to the third spacing D3.

In these optional embodiments, in the display panel further provided in the embodiments of the present disclosure, the display panel 10 includes a substrate 100, an isolation structure 300 and a light-emitting device 400. The isolation structure 300 is disposed on a side of the substrate 100, an isolation opening 301 is disposed on the isolation structure 300, the isolation opening includes a first opening 301a, a second opening 301b and a third opening 301c. The light-emitting device 400 includes a first-type device 401 disposed corresponding to the first opening 301a, a second-type device 402 disposed corresponding to the second opening 301b, and a third-type device 403 disposed corresponding to the third opening 301c. The isolation structure 300 may be configured to divide sub-pixels of the display panel 10.

The isolation structure 300 includes a first isolation portion 310 and a second isolation portion 320 located on a side of the first isolation portion 310 facing away from the substrate 100. The second isolation portion 320 is disposed to protrude from the first isolation portion 310 towards the isolation opening 301, so that when the light-emitting device 400 of the display panel 10 is prepared, an integral evaporation of a material of the light-emitting device 400 (such as, a material of the light-emitting layer 420 and a material of the second electrode 430) may be directly performed. The second isolation portion 320 may shield at least part of the material for preparing the light-emitting device 400, to partition the material of the light-emitting device 400 between adjacent sub-pixels and form a plurality of light-emitting devices 400 disposed at intervals and located in different isolation openings 301, so that when the light-emitting device 400 of the display panel 10 is prepared, it is not necessary to provide a finer mask, for example, when the material of the light-emitting device 400 is evaporated, it is not necessary to provide a fine metal mask, and thus the production and manufacturing cost of the display panel 10 can be better reduced.

The length of the protrusion of the second isolation portion 320 on a peripheral side of each isolation opening 301 is set reasonably, so that the isolating structure 300 on the peripheral side of each isolation opening 301 can be reasonably adjusted to shield and partition the material of the light-emitting device 400, so that the display effect of the display panel 10 can be improved.

Optionally, the display panel 10 further provided in the embodiments of the first aspect of the present disclosure may be the display panel 10 in any one of the foregoing embodiments, so that the display panel 10 further provided in the embodiments of the present disclosure may have the structure and beneficial effects of the display panel 10 in any one of the foregoing embodiments, and the details are not repeated in the present disclosure.

For example, the light-emitting device 400 may be the light-emitting device 400 in any one of the foregoing embodiments, the light-emitting device 400 may include the first-type device 401, the second-type device 402, the third-type device 403 and the fourth-type device 404 in any one of the embodiments, and the light-emitting device 400 includes a first electrode 410, a light-emitting layer 420 and a second electrode 430 which are laminated in sequence in a direction away from the substrate 100.

For example, the isolation structure 300 may be the isolation structure 300 in any one of the foregoing embodiments, and the isolation opening 301 in any one of the foregoing embodiments may be formed by enclosing the isolation structure 300. Specifically, the isolation opening 301 may include the first opening 301a, the second opening 301b, the third opening 301c and the fourth opening 301d in any one of the foregoing embodiments. The isolation structure 300 may include the conductive portion 330, the first isolation portion 310 and the second isolation portion 320 in any one of the foregoing embodiments, where the relative position relationship and the size relationship among the conductive portion 330, the first isolation portion 310 and the second isolation portion 320 may be set with reference to any one of the foregoing embodiments, where a side of at least part of the conductive portion 330 facing away from the substrate 100 has the dimple structure 10a.

Optionally, the display panel 10 further provided in the embodiments of the first aspect of the present disclosure may further include the pixel defining layer 200 in any one of the foregoing embodiments, and the pixel defining layer 200 may include the pixel defining portion 210 and the pixel opening 220 in any one of the foregoing embodiments. A side of at least part of the pixel defining portion 210 facing away from the substrate 100 may have the dimple structure 10a.

FIG. 9 is a schematic flowchart of a manufacturing method of a display panel 10 according to an embodiment of the present disclosure, and FIG. 10 to FIG. 36 are schematic diagrams of a manufacturing process of a manufacturing method of a display panel 10 according to an embodiment of the present disclosure.

An embodiment of a third aspect of the present disclosure provides a manufacturing method of a display panel. The display panel prepared by the manufacturing method may be the display panel 10 provided in the embodiments of any one of the first aspects described above. Referring to FIG. 9 in conjunction with FIGS. 1 to 8 and FIGS. 10 to 36, the manufacturing method includes steps described below.

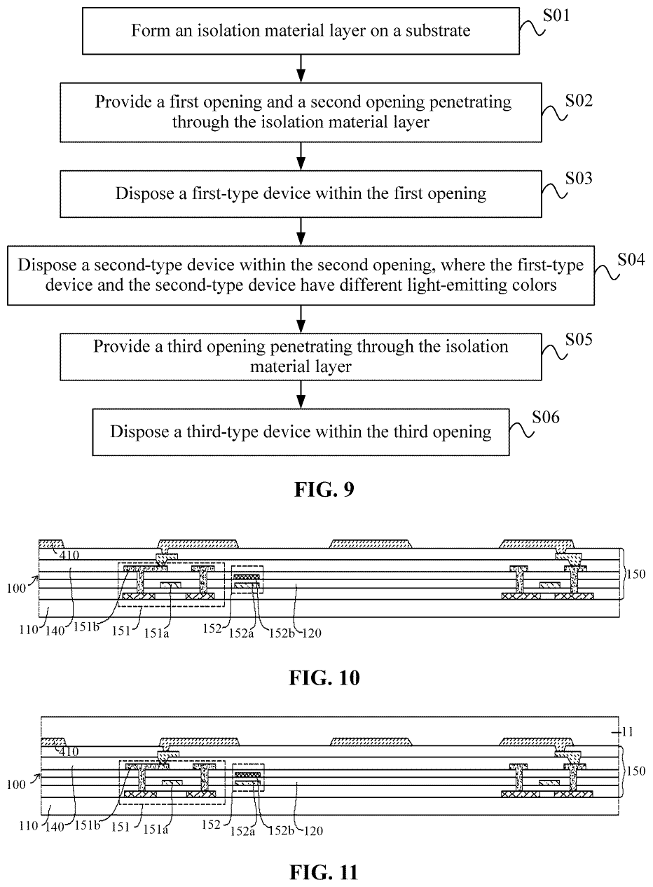

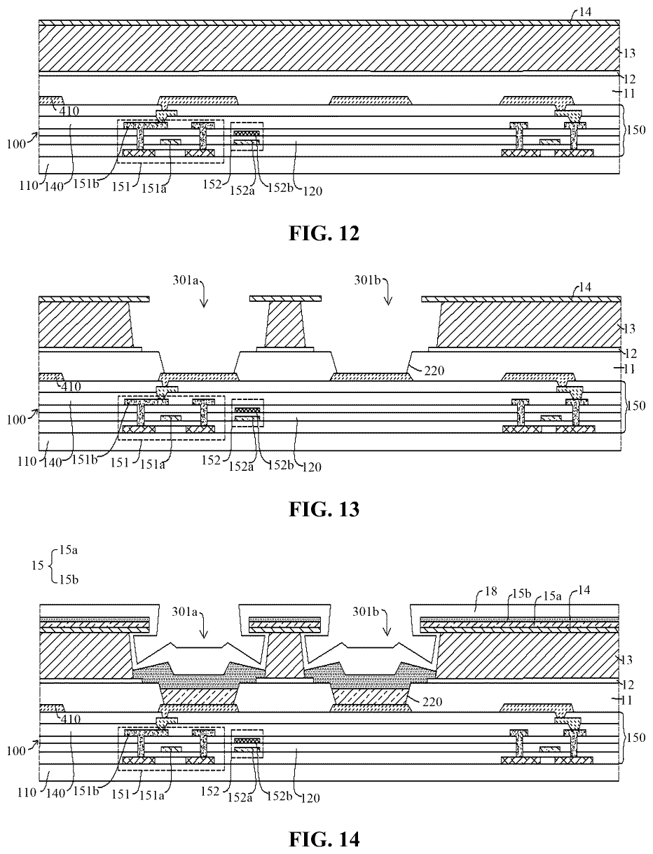

In step S01, as shown in FIG. 12, an isolation material layer is formed on a substrate.

In step S02, as shown in FIG. 13, a first opening and a second opening that penetrate through the isolation material layer are provided.

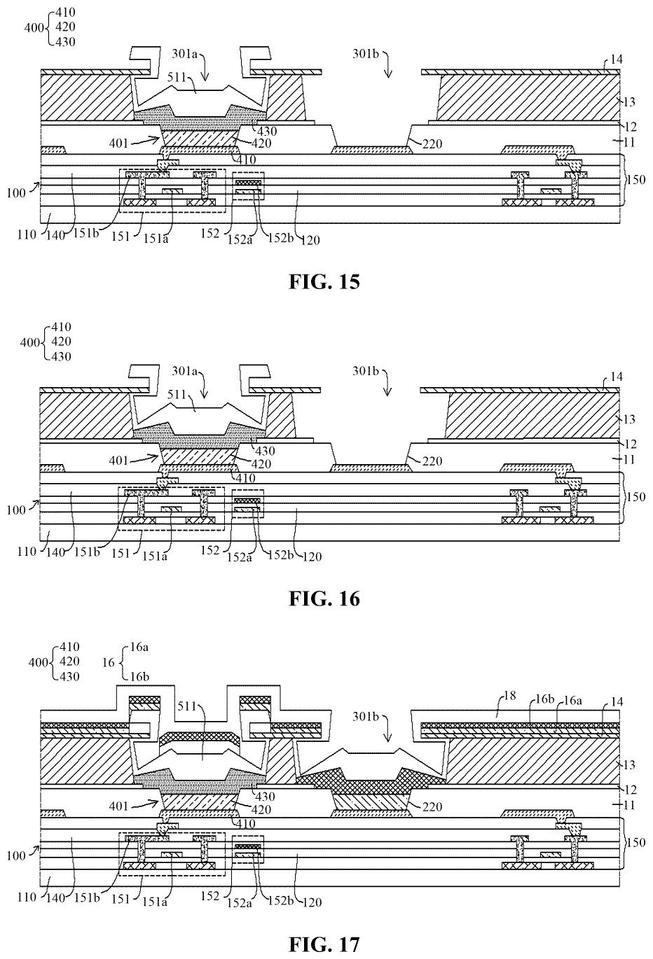

In step S03, as shown in FIGS. 14 and 15, a first-type device is disposed within the first opening.

In step S04, as shown in FIG. 16 to FIG. 18, a second-type device is disposed within the second opening, where the first-type device and the second-type device have different light-emitting colors.

In step S05, as shown in FIG. 19, a third opening that penetrates through the isolation material layer is provided.

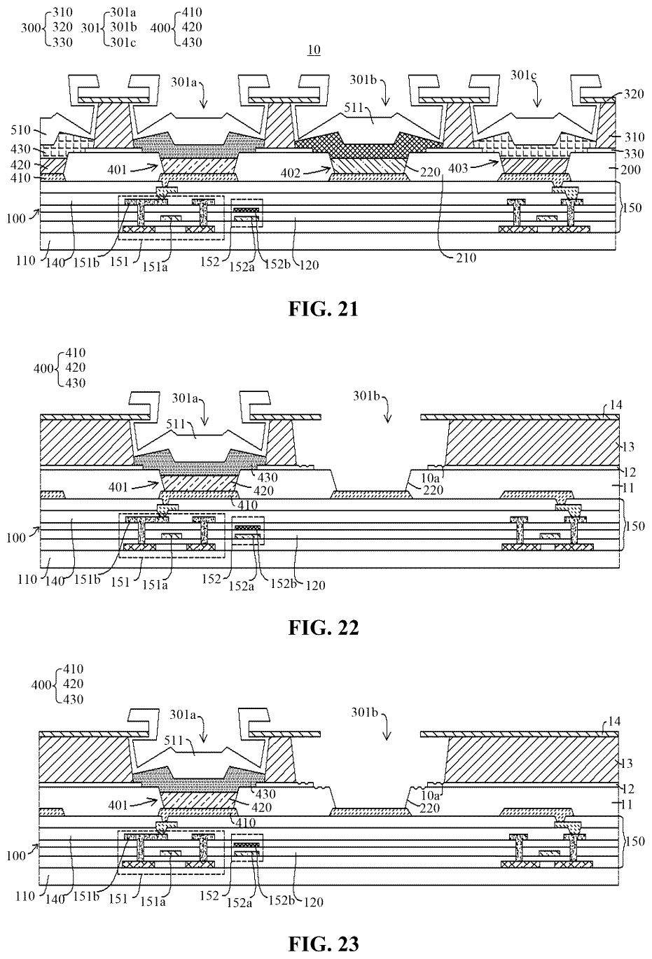

In step S06, as shown in FIGS. 20 and 21, a third-type device is disposed within the third opening.

In the embodiments of the present disclosure, the first-type device 401 and the second-type device 402 are prepared and then the third opening 301c is prepared, so that adverse effects on the preparation of the third-type device can be reduced. For example, the isolation structure 300 and the conductive portion 330 which are prepared subsequently and located on a peripheral side of the third opening 301c are not affected by the etching material, so that the conductive portion 330 which is formed by preparing and located on the peripheral side of the third opening 301c is not easy to be broken by the etching of the etching material, thereby greatly improving the connection reliability between the second electrode 430 of the third-type device 403 and the conductive portion 330 on the peripheral side of the third opening 301c. Since the etching material does not affect the conductive portion 330 on the peripheral side of the third opening 301c subsequently, the conductive portion 330 on the peripheral side of the third opening 301c may not have the dimple structure 10a.

In some optional embodiments, step S03 may include step S031

In step S031, as shown in FIG. 14, a first device material layer is prepared integrally.

The first device material layer 15 may be configured to form the first-type device 401 in any one of the foregoing embodiments.

Optionally, the first device material layer 15 may include a first light-emitting material layer 15a and a first-type electrode material layer 15b located on a side of the first light-emitting material layer 15a facing away from the substrate 100.

The first light-emitting material layer 15a may be configured to form the light-emitting layer 420 of the first-type device 401 in any one of the foregoing embodiments, and the first-type electrode material layer 15b may be configured to form the second electrode 430 of the first-type device 401 in any one of the foregoing embodiments.

Optionally, step S031 may further include: integrally preparing an encapsulation material layer 18 on the first device material layer 15. This part of the encapsulation material layer 18 may be configured to participate in forming an encapsulation unit 511 disposed corresponding to the first opening 301a.

In step S032, as shown in FIG. 15, the first device material layer within the second opening 301b is removed to form a first-type device disposed corresponding to the first opening.

Optionally, the first-type device 401 is connected to a conductive material layer 12 on a peripheral side of the first opening 301a.

Optionally, the second electrode 430 of the first-type device 401 is connected to the conductive material layer 12 on the peripheral side of the first opening 301a.

Optionally, step S032 may further include: removing the encapsulation material layer 18 outside the first opening 301a to form the encapsulation unit 511 disposed corresponding to the first opening 301a.

In some optional embodiments, the isolation material layer includes a first isolation material layer 13, a second isolation material layer 14 located on a side of the first isolation material layer 13 facing away from the substrate 100, and a conductive material layer 12 located on a side of the first isolation material layer 13 towards the substrate 100. The conductive material layer 12 may be configured to form the conductive portion 330 of the isolation structure 300 in any one of the foregoing embodiments. The first isolation material layer 13 may be configured to form the first isolation portion 310 of the isolation structure 300 in any one of the foregoing embodiments. The second isolation material layer 14 may be configured to form the second isolation portion 320 of the isolation structure 300 in any one of the foregoing embodiments.

Optionally, as shown in FIG. 22, the dimple structure 10a is disposed on the conductive material layer 12 on the peripheral side of the second opening 301b. In step S03, the conductive layer 12 on the peripheral side of the second opening 301b may be etched to a certain extent by using the etching material to form the dimple structure 10a.

Optionally, in step S03, as shown in FIG. 23, the dimple structure 10a is formed on the pixel defining material layer 11 exposed from the second opening.

Optionally, before step S04, the method may include steps described below.

As shown in FIG. 16, the second opening 301b is washed by using the etching material, and at least part of the first isolation material layer 13 is etched by using the etching material, so that the conductive material layer 12 is disposed to protrude towards the second opening 301b with respect to the first isolation material layer 13.

In this optional embodiment, the second opening 301b is washed by using the etching material, so that impurities within the second opening 301b are washed and removed, and meanwhile, an etching treatment may also be performed on the first isolation material layer 13 on the peripheral side of the second opening 301b by using the etching material, whereby a length of a protrusion of the conductive material layer 12 towards the first opening 301a with respect to the first isolation material layer 13 is less than a length of a protrusion of the conductive material layer 12 towards the second opening 301b with respect to the first isolation material layer 13, and subsequently a length of a protrusion of the conductive portion 330 towards the first opening 301a with respect to the first isolation portion 310 is less than a length of a protrusion of the conductive portion 330 towards the second opening 301b with respect to the first isolation portion 310. Optionally, step S04 may include step S041.

In step S041, as shown in FIG. 17, a second device material layer is prepared integrally.

Optionally, the second device material layer 16 may include a second light-emitting material layer 16a and a second-type electrode material layer 16b which is located on a side of the second light-emitting material layer 16a facing away from the substrate 100.

The second light-emitting material layer 16a may be configured to form the light-emitting layer 420 of the second-type device 402 in any one of the foregoing embodiments, and the second-type electrode material layer 16b may be configured to form the second electrode 430 of the second-type device 402 in any one of the foregoing embodiments.

Optionally, step S04 may further include: integrally preparing the encapsulation material layer 18 on the second device material layer 16. The part of encapsulation material layer 18 may be configured to participate in forming the encapsulation unit 511 disposed corresponding to the second opening 301b.

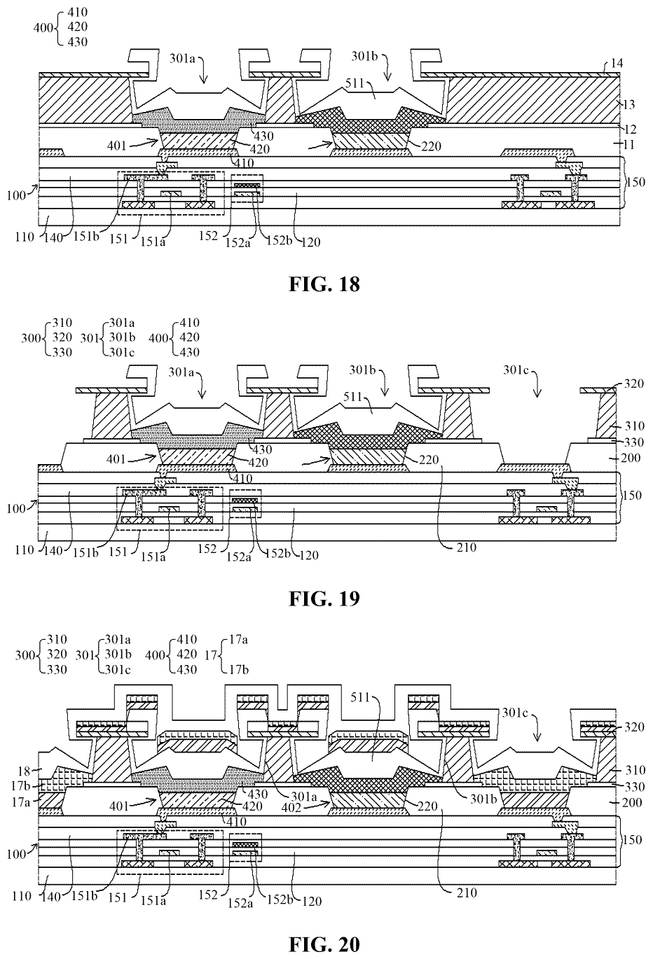

In step S042, as shown in FIG. 18, a second device material layer outside the second opening is removed, to form the second-type device disposed corresponding to the second opening.

Optionally, the second-type device 402 is connected to the conductive material layer 12 on the peripheral side of the second opening 301b, where the length of the protrusion of the conductive material layer 12 towards the first opening 301a with respect to the first isolation material layer 13 is less than a length of a protrusion of the conductive material layer 12 towards the second opening 301b with respect to the first isolation material layer 13.

Optionally, the second electrode 430 of the second-type device 402 is connected to the conductive material layer 12 on the peripheral side of the second opening 301b.

Optionally, step S042 may further include: removing the encapsulation material layer 18 outside the second opening 301b to form the encapsulation unit 511 disposed corresponding to the second opening 301b.

Step S06 includes step S061. In step S061, as shown in FIG. 20, a third device material layer is prepared integrally.

The third device material layer 17 may be configured to form the third-type device 403 in any one of the foregoing embodiments.

Optionally, the third device material layer 17 may include a third light-emitting material layer 17a and a third-type electrode material layer 17b, and the third-type electrode material layer 17b is located on a side of the third light-emitting material layer 17a facing away from the substrate 100.

The third light-emitting material layer 17a may be configured to form the light-emitting layer 420 of the third-type device 403 in any one of the foregoing embodiments, and the third-type electrode material layer 17b may be configured to form the second electrode 430 of the third-type device 403 in any one of the foregoing embodiments.

Optionally, step S061 may further include: integrally preparing the encapsulation material layer 18 on the third device material layer 17. The part of the encapsulation material layer 18 may be configured to participate in forming the encapsulation unit 511 disposed corresponding to the third opening 301c. In some optional embodiments, before step S061, the method may include: the third opening 301c is washed by using an etching material, and at least part of the first isolation material layer 310 is etched by using the etching material, so that a length of a protrusion of the conductive portion 330 towards the third opening 301c with respect to the first isolation portion 310 is greater than or equal to the length of the protrusion of the conductive portion 330 towards the first opening 301a with respect to the first isolation portion 310, or so that a length of a protrusion of the conductive portion 330 towards the third opening 301c with respect to the first isolation portion 310 is greater than or equal to the length of the protrusion of the conductive portion 330 towards the second opening 301b with respect to the first isolation portion 310.

In this optional embodiment, the third opening 301c is washed by using the etching material, so that impurities within the third opening 301c are washed and removed, and meanwhile, an etching treatment may also be performed on the first isolation material layer 13, by using the etching material, whereby the formed conductive portion 330 of the isolation structure 300 is disposed to protrude from the first isolation portion 310 towards the third opening 301c. The etching degree of the etching material to the first isolation material layer 13 on the peripheral side of the third opening 301c may be adjusted, so that the length of the protrusion of the conductive portion 330 towards the third opening 301c with respect to the first isolation portion 310 is greater than or equal to the length of the protrusion of the conductive portion 330 towards the first opening 301a with respect to the first isolation portion 310, or the length of the protrusion of the conductive portion 330 towards the third opening 301c with respect to the first isolation portion 310 is greater than or equal to the length of the protrusion of the conductive portion 330 towards the second opening 301b with respect to the first isolation portion 310.

In step S062: as shown in FIG. 21, the third device material layer outside the third opening is removed to form a third-type device disposed corresponding to the third opening.

Optionally, the third-type device 403 is connected to the conductive portion 330 on the circumferential side of the third opening 301c, where the length of the protrusion of the conductive portion 330 towards the third opening 301c with respect to the first isolation portion 310 is greater than or equal to the length of the protrusion of the conductive portion 330 towards the first opening 301a with respect to the first isolation portion 310.

Optionally, the length of the protrusion of the conductive portion 330 towards the third opening 301c with respect to the first isolation portion 310 is greater than or equal to the length of the protrusion of the conductive portion 330 towards the second opening 301b with respect to the first isolation portion 310.

Optionally, the second electrode 430 of the third-type device 403 is connected to the conductive material layer 12 on the peripheral side of the third opening 301c.

Optionally, step S062 may further include: removing the encapsulation material layer 18 outside the third opening 301c to form the encapsulation unit 511 disposed corresponding to the third opening 301c.

In some optional embodiments, before step S01, the manufacturing method further includes: a pixel defining material layer is formed on the substrate as shown in FIG. 10 and FIG. 11.

Step S01 includes: as shown in FIG. 12, forming the isolation material layer on the pixel defining material layer.

Step S02 includes: as shown in FIG. 13, patterning on the pixel defining material layer exposed from the first opening and the second opening to provide a plurality of pixel openings corresponding to the first opening and the second opening; and

Step S05 includes: as shown in FIG. 19, patterning on the pixel defining material exposed from the third opening to provide the pixel opening corresponding to the third opening.

In the embodiments of the present disclosure, before step S05, the third opening is not provided, so that the first electrode corresponding to the third opening is not exposed, and thus the damage to the first electrode caused by an etching process can be improved.

In some optional embodiments, step S03 includes: washing the first opening and the second opening by using the etching material, and etching at least part of the first isolation material layer by using the etching material, so that the conductive material layer is disposed to protrude from the first isolation material layer towards the first opening and the second opening; and disposing the first-type device within the first opening.

In these optional embodiments, the etching material is used to wash the first opening 301a and the second opening 301b, so that the conductive material layer 12 is disposed to protrude from the first isolation material layer 13 towards the first opening 301a and the second opening 301b. Moreover, an area of the conductive material layer 12 is relatively large, which facilitates the lapping of the second electrode 430 and the conductive material layer 12.

In some optional embodiments, when the isolation material layer includes the first isolation material layer 13, the second isolation material layer 14 located on the side of the first isolation material layer 13 facing away from the substrate 100, and the conductive material layer 12 located on the side of the first isolation material layer 13 towards the substrate 100, step S04 further includes: as shown in FIG. 16, washing the second opening by using the etching material, and etching at least part of the first isolation material layer by using the etching material, so that the conductive material layer is disposed to protrude from the first isolation material layer towards the second opening; and disposing the second-type device within the second opening.

In the embodiments of the present disclosure, after step S03, the second opening 301b is washed by using the etching material, so that the impact on the first-type device 401 can be improved, and the lapping effect between the second electrode 430 and the conductive material in the second-type device 402 can be improved.

Step S06 further includes step S063 and step S064. In step S063, the third opening is washed by using the etching material, and at least part of the first isolation material layer is etched by using the etching material, so that the conductive material layer is disposed to protrude from the first isolation material layer towards the third opening. In step S064, the third-type device is disposed within the third opening.

Optionally, step S064 may include the foregoing step S061 and step S062.

In some optional embodiments, in step S03, the dimple structure 10a is formed on the conductive material layer 12 exposed from the second opening 301b.

In some optional embodiments, step S02 is performed before step S05, or step S02 is performed after step S02. That is, after the first opening 301a and the second opening 301b are provided and the first-type device 401 and the second-type device 402 are prepared, the third opening 301c is provided and the third-type device 403 is prepared. Alternatively, after the third opening 301c is provided and the third-type device 403 is prepared, the first opening 301a and the second opening 301b are provided, and the first-type device 401 and the second-type device 402 are prepared.

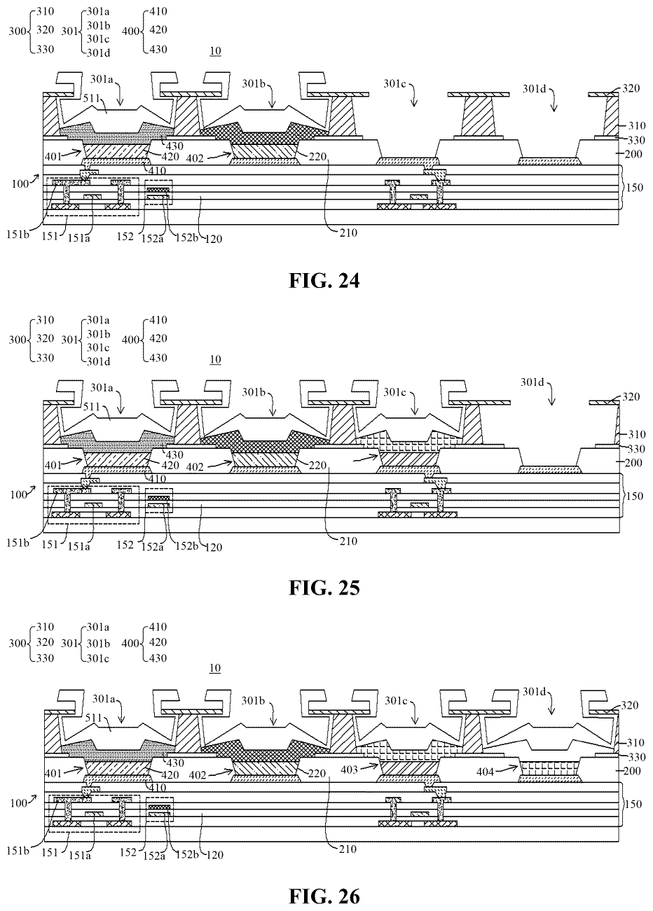

In some optional embodiments, step S05 further includes: as shown in FIG. 24, providing a fourth opening that penetrates through the isolation material layer. After step S04, for example, after step S06, the method further includes that: a fourth-type device is disposed within the fourth opening as shown in FIG. 25 and FIG. 26.

In these optional embodiments, the fourth opening 301d is further disposed, and the fourth-type device 404 is prepared. The fourth-type device 404 is provided so that the display effect of the display panel 10 can be improved. Moreover, the third opening 301c and the fourth opening 301d are disposed to be prepared together so that the preparation efficiency of the display panel 10 can be improved.

Optionally, step S06 may further include: as shown in FIG. 25, washing the fourth opening by using the etching material, and etching at least part of the first isolation material layer by using the etching material, so that the conductive material layer is disposed to protrude from the first isolation material layer towards the fourth opening.

In these optional embodiments, the fourth opening 301d is further washed in step S06, so that the conductive material layer 12 is disposed to be protrude from the first isolation material layer 13 towards the fourth opening 301d, thereby facilitating the lapping between the second electrode 430 of the fourth-type device 404 and the conductive material layer 12.

Optionally, step of washing the fourth opening 301d by using the etching material further includes: etching at least part of the first isolation material layer 13 by using the etching material, so that a length of a protrusion of the second isolation material layer 14 towards the third opening 301c with respect to the first isolation material layer 13 is less than a length of a protrusion of the second isolation material layer 14 towards the fourth opening 301d with respect to the first isolation material layer 13, thereby facilitating the lapping between the second electrode 430 of the fourth-type device 404 and the conductive material layer 12.

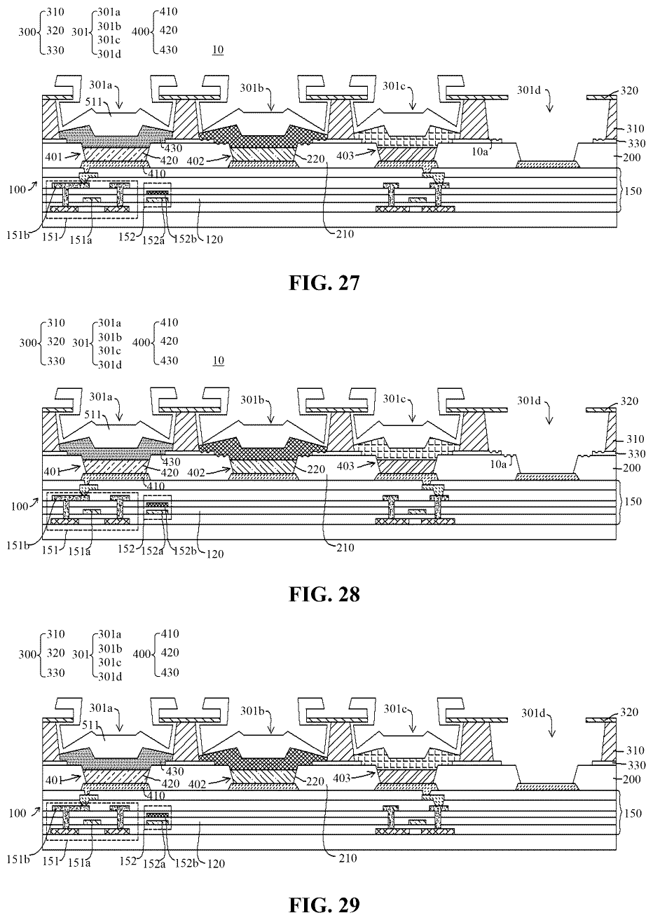

In some optional embodiments, step S06 includes: as shown in FIG. 27, etching, by using the etching material, the conductive material layer exposed from the fourth opening to form the dimple structure on the conductive material layer exposed from the fourth opening.

In these optional embodiments, when the third-type device 403 is prepared, for example, when a material for manufacturing the third-type device 403 in a region where the first opening 301a and the second opening 301b are located is removed by using the etching material, the conductive material layer 12 exposed from the fourth opening 301d is also etched, to form the dimple structure 10a.

In some optional embodiments, in step S05, providing a third opening 301c and a fourth opening 301d that penetrate through the isolation material layer, and patterning the pixel defining material layer 11 exposed from the third opening 301c and the fourth opening 301d to form the plurality of pixel openings 220 corresponding to the third opening 301c and the fourth opening 301d.

Optionally, step S06 includes: as shown in FIG. 28, etching, by using the etching material, the pixel defining material layer exposed from the fourth opening to form the dimple structure.

In these optional embodiments, in step S05, not only the third opening 301c and the fourth opening 301d are provided, but also the plurality of pixel openings 220 corresponding to the third opening 301c and the fourth opening 301d are provided in the pixel defining material layer 11, so that the preparation efficiency can be improved. In step S06, the fourth opening 301d is provided; therefore, part of the pixel defining material layer 11 will be exposed from the fourth opening 301d, and the part of the pixel defining material layer 11 is easy to be etched to form the dimple structure 10a in step S06.

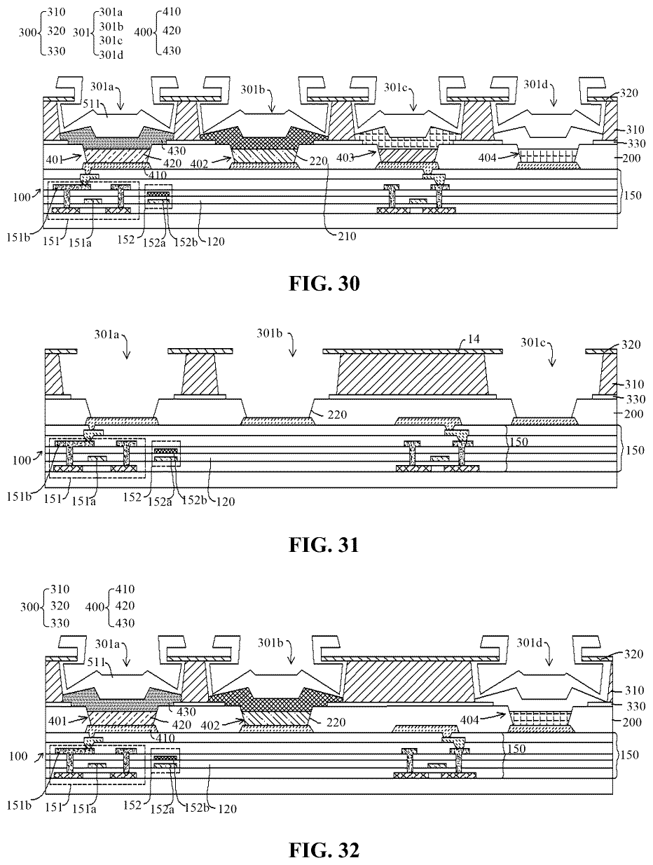

In some optional embodiments, the manufacturing method further includes step S07 and step S08. In step S07, as shown in FIG. 29, a fourth opening that penetrates through the isolation material layer is provided. In step S08, as shown in FIG. 30, a fourth-type device is disposed within the fourth opening. Step S07 is performed after step S05, or step S07 is performed between step S02 and step S05, or step S07 is performed before step S02.

In these optional embodiments, the fourth opening 301d is further provided and the fourth-type device 404 is prepared, and the fourth opening 301d may be provided and the fourth-type device 404 may be prepared before step S02, between step S02 and step S05, or after step S05, so that when other steps are performed, an inner wall of the fourth opening 301d is not easily damaged by etching.

In some optional embodiments, step S02 further includes: as shown in FIG. 31, providing a fourth opening penetrating through the isolation material layer.

After step S04, the method further includes: as shown in FIG. 32, a fourth-type device is disposed within the fourth opening.

In these optional embodiments, the first opening 301a, the second opening 301b and the fourth opening 301d are provided in the same process step, so that the manufacturing process can be simplified, and the preparation efficiency can be improved.

In some optional embodiments, when step S01 includes step S011 and step S012 described above, in step S02, a fourth opening 301d penetrating through the isolation material layer may be further provided, and the pixel defining material layer 11 exposed from the first opening 301a, the second opening 301b and the fourth opening 301d is patterned, to provide the plurality of pixel openings 220 corresponding to the first opening 301a and the second opening 301b and the fourth opening 301d.

In these optional embodiments, the first opening 301a, the second opening 301b and the fourth opening 301d are provided synchronously in step S02, so that the manufacturing process can be simplified.

Optionally, step S03 includes: washing, by using the etching material, the first opening, the second opening and the fourth opening, and etching, by using the etching material, at least part of the first isolation material layer, so that the conductive material layer is disposed to protrude from the first isolation material layer towards the first opening, the second opening and the fourth opening; and disposing the first-type device within the first opening.

In these optional embodiments, the fourth opening 301d is washed by the etching material, so that the conductive material layer 12 is disposed to protrude from the first isolation material layer 13 towards the fourth opening 301d, thereby facilitating the mutual lapping between the first electrode 410 of the fourth-type device 404 and the conductive material layer 12.

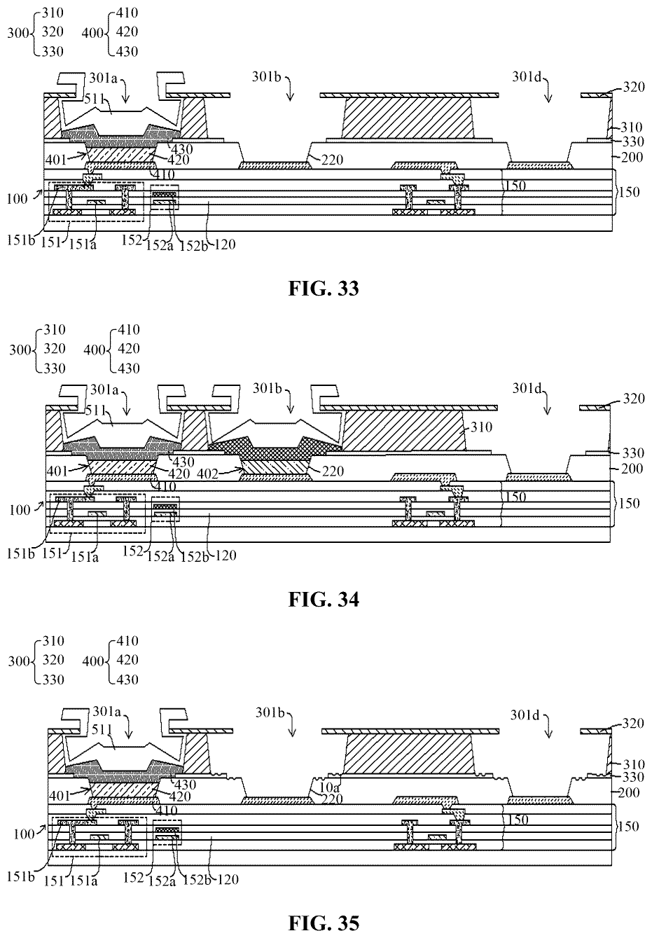

Optionally, step S04 further includes, as shown in FIG. 33, washing the second opening and the fourth opening by using the etching material, and etching at least part of the first isolation material layer by using the etching material, so that the conductive material layer is disposed to protrude from the first isolation material layer towards the second opening and the fourth opening.

In these optional embodiments, the second opening 301b and the fourth opening 301d are washed by using the etching material, so that the conductive material layer 12 may have a longer length of a protrusion towards the second opening 301b and the fourth opening 301d compared to the first isolation material layer 13, thereby facilitating the mutual lapping of the first electrodes 410 of the second-type device 402 and the fourth-type device 404 and the conductive material layer 12.

Optionally, step of washing the second opening 301b and the fourth opening 301d by using the etching material further includes: etching at least part of the first isolation material layer 13 by using the etching material, so that a length of a protrusion of the second isolation material layer 14 towards the first opening 301a with respect to the first isolation material layer 13 is less than a length of a protrusion of the second isolation material layer 14 towards the second opening 301b and the fourth opening 301d with respect to the first isolation material layer 13, thereby facilitating the mutual lapping between the first electrodes 410 of the second-type device 402 and the fourth-type device 404 and the conductive material layer 12.

In some optional embodiments, after S04, the method may include: as shown in FIG. 34, the fourth opening is washed by using the etching material, and at least part of the first isolation material layer is etched by using the etching material, so that the conductive material layer is disposed to protrude from the first isolation material layer towards the fourth opening.

In these optional embodiments, the fourth opening 301d may also be washed by the etching material, so that the conductive material layer 12, compared with the first isolation material layer 13, may have a longer length of a protrusion towards the fourth opening 301d, thereby further facilitating the mutual lapping between the first electrode 410 of the fourth-type device 404 and the conductive material layer 12.

Optionally, step of washing the fourth opening 301d by using the etching material further includes: etching, by using the etching material, at least part of the first isolation material layer 13, so that the length of the protrusion of the second isolation material layer 14 towards the first opening 301a and the second opening 301b with respect to the first isolation material layer 13 is less than the length of the protrusion of the second isolation material layer 14 towards the fourth opening 301d with respect to the first isolation material layer 13, thereby facilitating the mutual lapping of the first electrode 410 of the fourth-type device 404 and the conductive material layer 12.

Optionally, step S03 includes: as shown in FIG. 35, etching, by using the etching material, the pixel defining material layer exposed from the second opening and the fourth opening to form the dimple structure on the pixel defining material layer exposed from the second opening and the fourth opening.

In these optional embodiments, the first opening 301a, the second opening 301b and the fourth opening 301d are provided in step S02; therefore, when the material, for preparing the first-type device 401, of the second opening 301b and the fourth opening 301d is etched, the etching material may affect the pixel defining material layer 11 exposed from the second opening 301b and the fourth opening 301d to form the dimple structure 10a.

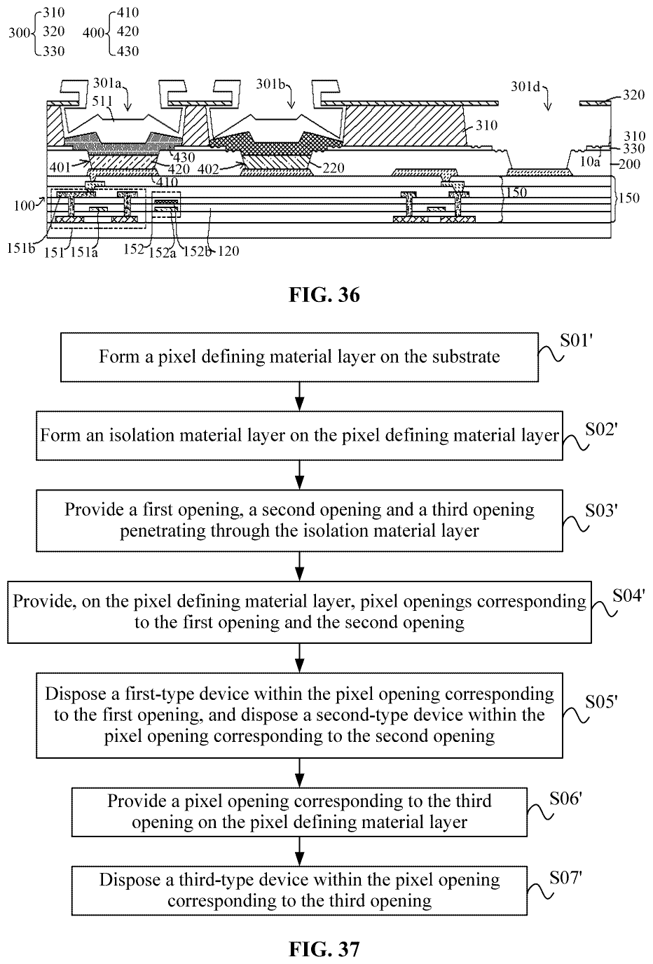

Step S04 includes: as shown in FIG. 36, etching, by using the etching material, the pixel defining material layer exposed from the fourth opening to form the dimple structure on the pixel defining material layer exposed from the fourth opening.

As described above, the first opening 301a, the second opening 301b and the fourth opening 301d are provided in step S02; therefore, when the material for manufacturing the second-type device 402 in the fourth opening 301d is etched in step S04, the etching material may affect the pixel defining material layer 11 exposed from the fourth opening 301d to form the dimple structure 10a.

In some optional embodiments, step S03 includes: as shown in FIG. 35, etching, by using the etching material, the conductive material layer exposed from the second opening and the fourth opening, and forming the dimple structure 10a on the conductive material layer exposed from the second opening and the fourth opening.

In the optional embodiment, the dimple structure 10a is formed on the conductive material layer 12 exposed from the second opening 301b and the fourth opening 301d, so that the lapping effect between the second electrodes 430 in the second-type component 402 and the fourth-type device 404 and the conductive material can be improved.

In some optional embodiments, step S04 includes: as shown in FIG. 36, etching, by using the etching material, the conductive material layer exposed from the fourth opening, and forming the dimple structure on the conductive material layer exposed from the fourth opening.

In this optional embodiment, the dimple structure 10a is formed on the conductive material layer 12 exposed from the fourth opening 301d so that the lapping effect of the second electrode 430 in the fourth-type device 404 and the conductive material can be improved.

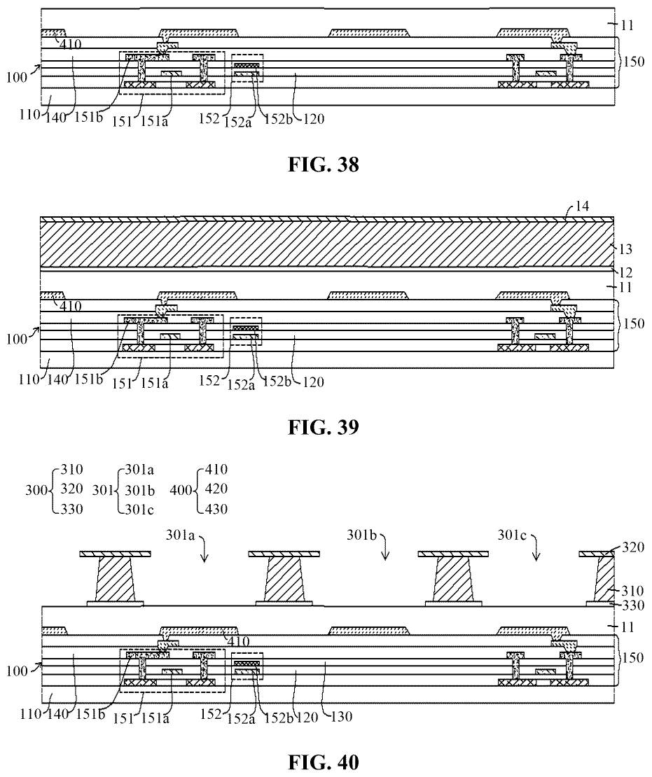

FIG. 37 is a schematic flowchart of a manufacturing method of a display panel 10 according to an embodiment of the present disclosure, and FIG. 38 to FIG. 44 are schematic diagrams of a manufacturing process of a manufacturing method of a display panel 10 according to an embodiment of the present disclosure.

An embodiment of the third aspect of the present disclosure further provides a manufacturing method of the display panel 10. The display panel prepared by the manufacturing method may be the display panel 10 provided in the embodiments of any one of the first aspects described above. Please referring to FIG. 37 in combination with FIGS. 1 to 8 and FIGS. 38 to 44, the manufacturing method includes steps described below.

In step S01′, as shown in FIG. 38, a pixel defining material layer is formed on the substrate.

In step S02′, as shown in FIG. 39, an isolation material layer is formed on the pixel defining material layer.

In step S03′, as shown in FIG. 40, a first opening, a second opening and a third opening that penetrate through the isolation material layer are provided.

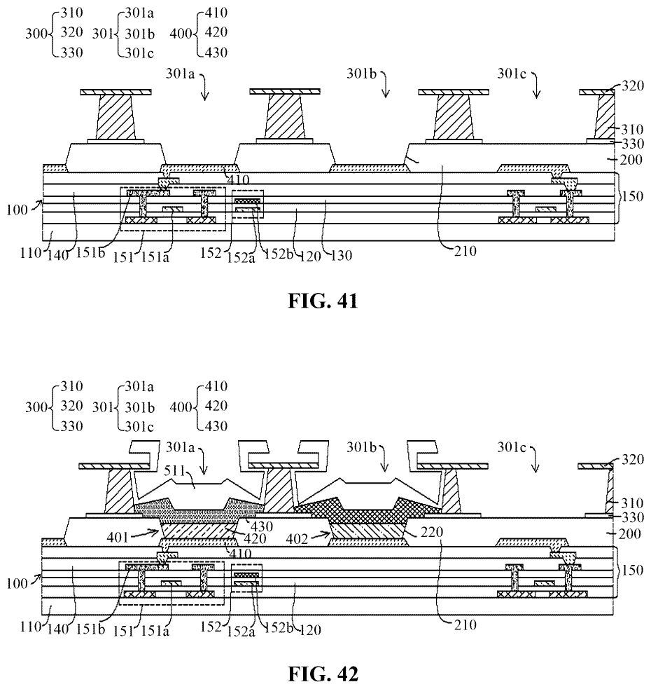

In step S04′, as shown in FIG. 41, a plurality of pixel openings corresponding to the first opening and the second opening are provided on the pixel defining material layer.

In step S05′, as shown in FIG. 42, a first-type device is disposed within the pixel opening corresponding to the first opening, and a second-type device is disposed within the pixel opening corresponding to the second opening.

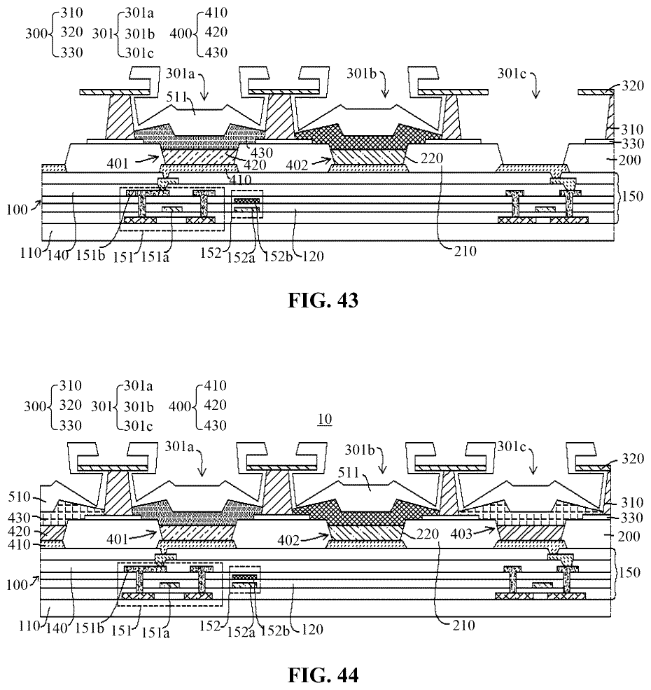

In step S06′, as shown in FIG. 43, a pixel opening corresponding to the third opening is provided on the pixel defining material layer.

In step S07′, as shown in FIG. 44, a third-type device is disposed within the pixel opening corresponding to the third opening.

In the embodiments of the present disclosure, different the plurality of pixel openings 220 are provided in step S04′ and step S06′, for example, step S04′ is performed before step S06′, then in step S05′, a pixel defining material corresponding to the third opening 301c can provide protection for the underlying first electrode 410, so that the influence of the etching material on the first electrode 410 corresponding to the subsequently prepared third opening 301c can be improved. Alternatively, step S04′ is performed after step S06′, then in step S07′, pixel defining materials corresponding to the first opening 301a and the second opening 301b may provide protection for the underlying first electrode 410, so that the influence of the etching material on the first electrode 410 corresponding to the subsequently prepared third opening 301c can be improved.

In some optional embodiments, step S04′ may be performed before step S06′, or step S04′ may be performed after step S06′, as long as step S04′ and step S06′ are in two different process steps.

An embodiment of the third aspect of the present disclosure provides a display device, and the display device includes the display panel 10 in any one of the above-described embodiments. The display device provided in the embodiment of the third aspect of the present disclosure includes the display panel 10 in any one of the embodiments of the first aspect described above, or includes the display panel 10 prepared by the manufacturing method in any one of the embodiments of the second aspect described above. Therefore, the display device provided in the embodiment of the third aspect of the present disclosure has beneficial effects possessed by the display panel 10 in any one of the embodiments of the first aspect described above or possessed by the display panel 10 prepared by the manufacturing method in any one of the embodiments of the second aspect described above, which will not be repeated here.

The display device in the embodiments of the present disclosure includes, but is not limited to, an apparatus that has the display function, such as a mobile phone, a personal digital assistant (PDA), a tablet computer, an electronic book, a television set, a access control, an intelligent fixed telephone, and a console.

According to the above-described embodiments of the present disclosure, all details are not described in detail in these embodiments, and these embodiments are also not limited to only specific embodiments of the present disclosure. Apparently, many modifications and changes may be made according to the foregoing description. This specification selects and specifically describes these embodiments to better explain principles and practical applications of the present disclosure, so that those skilled in the art can make good use of the present disclosure and the amendments made on the basis of the present disclosure. The present disclosure is only limited by the claims and all the scope and equivalents thereof.

What is claimed is:

1. A display panel, comprising:
a substrate;
a pixel defining layer, wherein the pixel defining layer is disposed on a side of the substrate and comprises a pixel defining portion and a plurality of pixel openings formed by enclosing the pixel defining portion;
an isolation structure, wherein the isolation structure is disposed on a side of the substrate, a plurality of isolation openings are disposed on the isolation structure, and the plurality of isolation openings communicate with the plurality of pixel openings; and
a plurality of light-emitting devices at least partially located within the plurality of pixel openings,
wherein the pixel defining portion exposed from at least part of the plurality of isolation openings has a dimple structure disposed on a side facing away from the substrate.

2. The display panel of claim 1, wherein the plurality of isolation openings comprise a first opening and a second opening, the plurality of light-emitting devices comprise a first-type device disposed corresponding to the first opening and a second-type device disposed corresponding to the second opening, the first-type device and the second-type device have different light-emitting colors, and the pixel defining portion exposed from the second opening has the dimple structure disposed on the side facing away from the substrate;
the pixel defining portion exposed from the first opening has a first flat surface disposed on the side facing away from the substrate;
the plurality of isolation openings further comprise a third opening, the plurality of light-emitting devices comprise a third-type device disposed corresponding to the third opening, the pixel defining portion exposed from the third opening has the dimple structure disposed on the side facing away from the substrate, or the pixel defining portion exposed from the third opening has the first flat surface disposed on the side facing away from the substrate.

3. The display panel of claim 2, wherein the plurality of isolation openings further comprise a fourth opening, the plurality of light-emitting devices comprise a fourth-type device disposed corresponding to the fourth opening, the pixel defining portion exposed from the fourth opening has the dimple structure disposed on the side facing away from the substrate, or the pixel defining portion exposed from the fourth opening has the first flat surface disposed on the side facing away from the substrate; and
the first-type device is a light-emitting device emitting blue light, the second-type device is a light-emitting device emitting green light, the third-type device is a light-emitting device emitting red light, and the fourth-type device is a light-emitting device emitting white light.

4. The display panel of claim 1, wherein a film layer of the plurality of light-emitting devices is partially located within the dimple structure; and
each of the plurality of light-emitting devices comprises a first electrode, a light-emitting layer and a second electrode which are laminated in sequence in a direction away from the substrate, wherein the light-emitting layer is partially located within the dimple structure, and the second electrode is partially located within the dimple structure;
wherein one dimple structure or a plurality of dimple structures are provided, the plurality of dimple structures are disposed at intervals, or the plurality of dimple structures are connected to each other.

5. The display panel of claim 1, wherein the isolation structure comprises a first isolation portion and a second isolation portion located on a side of the first isolation portion facing away from the substrate, and the second isolation portion has a first protrusion portion disposed to protrude from the first isolation portion towards the plurality of isolation openings; and
an orthographic projection of the dimple structure on the substrate is at least partially located within an orthographic projection of the first protrusion portion on the substrate.

6. The display panel of claim 5, wherein the plurality of isolation openings comprise a first opening and a second opening, the plurality of light-emitting devices comprise a first-type device disposed corresponding to the first opening and a second-type device disposed corresponding to the second opening, and a length of a protrusion of the second isolation portion towards the first opening with respect to the first isolation portion is less than a length of a protrusion of the second isolation portion towards the second opening with respect to the first isolation portion.

7. The display panel of claim 6, wherein the side of the first isolation portion facing away from the substrate has a first surface, a side of the second isolation portion towards the substrate has a second surface, a first spacing exists between an orthographic projection of an edge of the first opening corresponding to the first surface on the substrate and an orthographic projection of an edge of the first opening corresponding to the second surface on the substrate, a second spacing exists between an orthographic projection of an edge of the second opening corresponding to the first surface on the substrate and an orthographic projection of an edge of the second opening corresponding to the second surface on the substrate, and the first spacing is less than the second spacing; and
a side of the first isolation portion close to the substrate has a third surface, a third spacing exists between an orthographic projection of an edge of the first opening corresponding to the third surface on the substrate and the orthographic projection of the edge of the first opening corresponding to the second surface on the substrate, a fourth spacing exists between an orthographic projection of an edge of the second opening corresponding to the third surface on the substrate and an orthographic projection of the edge of the second opening corresponding to the second surface on the substrate, and the third spacing is less than the fourth spacing.

8. The display panel of claim 6, wherein the plurality of isolation openings further comprise a third opening, the plurality of light-emitting devices comprise a third-type device disposed corresponding to the third opening, a length of a protrusion of the second isolation portion towards the third opening with respect to the first isolation portion is not less than the length of the protrusion of the second isolation portion towards the first opening with respect to the first isolation portion, and/or a length of a protrusion of the second isolation portion towards the third opening with respect to the first isolation portion is not greater than the length of the protrusion of the second isolation portion towards the second opening with respect to the first isolation portion.

9. The display panel of claim 8, wherein a fifth spacing exists between an orthographic projection of an edge of the third opening corresponding to the first surface on the substrate and an orthographic projection of an edge of the third opening corresponding to the second surface on the substrate, the fifth spacing is not less than the first spacing, and/or the fifth spacing is not greater than the second spacing; and
a sixth spacing exists between an orthographic projection of an edge of the third opening corresponding to the third surface on the substrate and the orthographic projection of the edge of the third opening corresponding to the second surface on the substrate, the sixth spacing is not less than the third spacing, and/or the sixth spacing is not greater than the fourth spacing.

10. The display panel of claim 8, wherein the plurality of isolation openings further comprise a fourth opening, the plurality of light-emitting devices comprise a fourth-type device disposed corresponding to the fourth opening, and a length of a protrusion of the second isolation portion towards the fourth opening with respect to the first isolation portion is greater than or equal to the length of the protrusion of the second isolation portion towards the third opening with respect to the first isolation portion.

11. The display panel of claim 10, wherein a seventh spacing exists between an orthographic projection of an edge of the fourth opening corresponding to the first surface on the substrate and an orthographic projection of an edge of the fourth opening corresponding to the second surface on the substrate, the seventh spacing is not less than the first spacing, and/or the seventh spacing is not greater than the second spacing;
a fifth spacing exists between an orthographic projection of an edge of the third opening corresponding to the first surface on the substrate and an orthographic projection of an edge of the third opening corresponding to the second surface on the substrate, and the seventh spacing is greater than or equal to the fifth spacing;
an eighth spacing exists between an orthographic projection of an edge of the fourth opening corresponding to the third surface on the substrate and the orthographic projection of the edge of the fourth opening corresponding to the second surface on the substrate, the eighth spacing is not less than the third spacing, and/or the eighth spacing is not greater than the fourth spacing; and
a sixth spacing exists between an orthographic projection of an edge of the third opening corresponding to the third surface on the substrate and the orthographic projection of the edge of the third opening corresponding to the second surface on the substrate, and the eighth spacing is greater than or equal to the sixth spacing.

12. The display panel of claim 5, wherein the isolation structure further comprises a conductive portion disposed on a side of the first isolation portion towards the substrate, the conductive portion has a second protrusion portion disposed to protrude from the first isolation portion towards the plurality of isolation openings, and the second protrusion portion of at least part of the conductive portion has the dimple structure disposed on a side facing away from the substrate;
the plurality of isolation openings comprise a first opening and a second opening, the plurality of light-emitting devices comprise a first-type device disposed corresponding to the first opening and a second-type device disposed corresponding to the second opening, and the second protrusion portion disposed to protrude from the first isolation portion towards the second opening has the dimple structure disposed on the side facing away from the substrate;
the second protrusion portion disposed to protrude from the first isolation portion towards the first opening has a second flat surface disposed on the side facing away from the substrate, the plurality of isolation openings further comprise a third opening, the plurality of light-emitting devices comprise a third-type device disposed corresponding to the third opening, the second protrusion portion disposed to protrude from the first isolation portion towards the third opening has the dimple structure disposed on the side facing away from the substrate, or the second protrusion portion disposed to protrude from the first isolation portion towards the third opening has the second flat surface disposed on the side facing away from the substrate; and
the plurality of isolation openings further comprise a fourth opening, the plurality of light-emitting devices comprise a fourth-type device disposed corresponding to the fourth opening, the second protrusion portion disposed to protrude from the first isolation portion towards the fourth opening has the dimple structure disposed on the side facing away from the substrate, or the second protrusion portion disposed to protrude from the first isolation portion towards the fourth opening has the second flat surface disposed on the side facing away from the substrate.

13. The display panel of claim 12, wherein the plurality of light-emitting devices is partially located within the dimple structure of the conductive portion;
the plurality of light-emitting devices comprise a first electrode, a light-emitting layer and a second electrode which are laminated in sequence in a direction away from the substrate, the second electrode is connected to the conductive portion, and the second electrode is partially located within the dimple structure of the conductive portion; and
the second electrode is further connected to the first isolation portion.

14. The display panel of claim 1, wherein the plurality of isolation openings comprise a first opening and a second opening, the plurality of light-emitting devices comprise a first-type device disposed corresponding to the first opening and a second-type device disposed corresponding to the second opening, the isolation structure comprises a first isolation portion and a conductive portion located on a side of the first isolation portion towards the substrate, and a length of a protrusion of the conductive portion towards the first opening with respect to the first isolation portion is less than a length of a protrusion of the conductive portion towards the second opening with respect to the first isolation portion;
the length of the protrusion of the conductive portion towards the first opening with respect to the first isolation portion ranges from 0.05 micrometers to 0.4 micrometers;
the length of the protrusion of the conductive portion towards the second opening with respect to the first isolation portion is greater than the length of the protrusion of the conductive portion towards the first opening with respect to the first isolation portion, and is not greater than 3 times the length of the protrusion of the conductive portion towards the first opening with respect to the first isolation portion; and
the length of the protrusion of the conductive portion towards the second opening with respect to the first isolation portion is not less than 3/2 times the length of the protrusion of the conductive portion towards the first opening with respect to the first isolation portion, and not greater than 2 times the length of the protrusion of the conductive portion towards the first opening with respect to the first isolation portion.

15. The display panel of claim 14, wherein the plurality of isolation openings further comprise a third opening, the plurality of light-emitting devices comprise a third-type device disposed corresponding to the third opening, a length of a protrusion of the conductive portion towards the third opening with respect to the first isolation portion is not less than a length of a protrusion of the conductive portion towards the first opening with respect to the first isolation portion, and/or a length of a protrusion of the conductive portion towards the third opening with respect to the first isolation portion is not greater than a length of a protrusion of the conductive portion towards the second opening with respect to the first isolation portion; and
the plurality of isolation openings further comprise a fourth opening, the plurality of light-emitting devices comprise a fourth-type device disposed corresponding to the fourth opening, and a length of a protrusion of the conductive portion towards the fourth opening with respect to the first isolation portion is greater than or equal to a length of a protrusion of the conductive portion towards the third opening with respect to the first isolation portion.

16. A display panel, comprising:
a substrate;
an isolation structure disposed on a side of the substrate, wherein a plurality of isolation openings are disposed on the isolation structure, the isolation structure comprises a first isolation portion and a conductive portion disposed on a side of the first isolation portion towards the substrate, and the conductive portion has a second protrusion portion disposed to protrude from the first isolation portion towards the plurality of isolation openings; and
a plurality of light-emitting devices at least partially located within the plurality of isolation openings;
wherein the second protrusion portion of at least part of the conductive portion has a dimple structure on a side facing away from the substrate.

17. The display panel of claim 16, wherein the plurality of isolation openings comprise a first opening and a second opening, the plurality of light-emitting devices comprise a first-type device disposed corresponding to the first opening and a second-type device disposed corresponding to the second opening, and the second protrusion portion disposed to protrude from the first isolation portion towards the second opening has the dimple structure disposed on the side facing away from the substrate;
the second protrusion portion disposed to protrude from the first isolation portion towards the first opening has a second flat surface disposed on the side facing away from the substrate;
the plurality of isolation openings further comprise a third opening, the plurality of light-emitting devices comprise a third-type device disposed corresponding to the third opening, the second protrusion portion disposed to protrude from the first isolation portion towards the third opening has the dimple structure disposed on the side facing away from the substrate, or the second protrusion portion disposed to protrude from the first isolation portion towards the third opening has the second flat surface disposed on the side facing away from the substrate.

18. The display panel of claim 17, wherein the plurality of isolation openings further comprise a fourth opening, the plurality of light-emitting devices comprise a fourth-type device disposed corresponding to the fourth opening, the second protrusion portion disposed to protrude from the first isolation portion towards the fourth opening has the dimple structure disposed on the side facing away from the substrate, or the second protrusion portion disposed to protrude from the first isolation portion towards the fourth opening has the second flat surface disposed on the side facing away from the substrate.

19. The display panel of claim 16, wherein the plurality of light-emitting devices are partially located within the dimple structure; and
each of the plurality of light-emitting devices comprises a first electrode, a light-emitting layer, and a second electrode which are laminated in sequence in a direction away from the substrate, the second electrode is connected to the conductive portion, and the second electrode is partially located within the dimple structure; and
one dimple structure or a plurality of dimple structures are provided, the plurality of dimple structures are disposed at intervals, and/or the plurality of dimple structures are connected to each other.

20. A manufacturing method of a display panel, comprising:
forming an isolation material layer on a substrate;
providing a first opening and a second opening that penetrate through the isolation material layer;
disposing a first-type device within the first opening;
disposing a second-type device within the second opening, wherein the first-type device and the second-type device have different light-emitting colors;
providing a third opening that penetrates through the isolation material layer; and
disposing a third-type device within the third opening.

21. The manufacturing method of claim 20, wherein the disposing the first-type device within the first opening comprises: integrally preparing a first device material layer; and removing the first device material layer within the second opening to form the first-type device disposed corresponding to the first opening;
wherein the disposing the second-type device within the second opening comprises: integrally preparing a second device material layer; and removing the second device material layer outside the second opening to form the second-type device disposed corresponding to the second opening; and
wherein the disposing the third-type device within the third opening comprises: integrally preparing a third device material layer; and removing the third device material layer outside the third opening to form the third-type device disposed corresponding to the third opening.

22. The manufacturing method of claim 20, wherein before the forming the isolation material layer on the substrate, the method further comprises: forming a pixel defining material layer on the substrate;
wherein the forming the isolation material layer on the substrate comprises: forming the isolation material layer on the pixel defining material layer;
wherein the providing the first opening and the second opening that penetrate through the isolation material layer comprises: patterning the pixel defining material layer exposed from the first opening and the second opening, to provide a plurality of pixel openings corresponding to the first opening and the second opening;
wherein the providing the third opening that penetrates through the isolation material layer comprises: patterning on the pixel defining material layer exposed from the third opening, to provide a pixel opening corresponding to the third opening; and
wherein the disposing the first-type device within the first opening comprises: forming a dimple structure on the pixel defining material layer exposed from the second opening.

23. The manufacturing method of claim 20, wherein the isolation material layer comprises a first isolation material layer, a second isolation material layer located on a side of the first isolation material layer facing away from the substrate, and a conductive material layer located on a side of the first isolation material layer towards the substrate;
wherein the disposing the first-type device within the first opening comprises:
washing the first opening and the second opening by using an etching material, and etching at least part of the first isolation material layer by using the etching material, so that the conductive material layer is disposed to protrude from the first isolation material layer towards the first opening and the second opening; and
disposing the first-type device within the first opening.

24. The manufacturing method of claim 20, wherein the isolation material layer comprises a first isolation material layer, a second isolation material layer located on a side of the first isolation material layer facing away from the substrate, and a conductive material layer located on a side of the first isolation material layer towards the substrate;
wherein the disposing the second-type device within the second opening comprises:
washing the second opening by using an etching material, and etching at least part of the first isolation material layer by using the etching material, so that the conductive material layer is disposed to protrude from the first isolation material layer towards the second opening; and
disposing the second-type device within the second opening;
the washing the second opening by using the etching material further comprises:
etching at least part of the first isolation material layer by using the etching material, so that a length of a protrusion of the second isolation material layer towards the first opening with respect to the first isolation material layer is less than a length of a protrusion of the second isolation material layer towards the second opening with respect to the first isolation material layer.

25. The manufacturing method of claim 20, wherein the isolation material layer comprises a first isolation material layer, a second isolation material layer located on a side of the first isolation material layer facing away from the substrate, and a conductive material layer located on a side of the first isolation material layer towards the substrate;
wherein the disposing the third-type device within the third opening comprises:
washing the third opening by using an etching material, and etching at least part of the first isolation material layer by using the etching material, so that the conductive material layer is disposed to protrude from the first isolation material layer towards the third opening; and
disposing the third-type device within the third opening.

26. The manufacturing method of claim 20, wherein the isolation material layer comprises a first isolation material layer and a conductive material layer located on a side of the first isolation material layer towards the substrate; and
wherein the disposing the first-type device within the first opening comprises: forming a dimple structure on the conductive material layer exposed from the second opening.

27. The manufacturing method of claim 20, wherein the providing the first opening and the second opening that penetrate through the isolation material layer is before the providing the third opening that penetrates through the isolation material layer; or
the providing the first opening and the second opening that penetrate through the isolation material layer is after the providing the third opening that penetrates through the isolation material layer.

28. The manufacturing method of claim 20, wherein the providing the third opening that penetrates through the isolation material layer comprises: providing a fourth opening that penetrates through the isolation material layer; and
wherein after the disposing the third-type device within the third opening, the method further comprises: disposing a fourth-type device within the fourth opening.

29. The manufacturing method of claim 20, wherein the manufacturing method further comprises:
providing a fourth opening that penetrates through the isolation material layer; and
disposing a fourth-type device within the fourth opening;
wherein the providing the fourth opening that penetrates through the isolation material layer is after the providing the third opening that penetrates through the isolation material layer, or the providing the fourth opening that penetrates through the isolation material layer is between the providing the first opening and the second opening that penetrate through the isolation material layer and the providing the third opening that penetrates through the isolation material layer, or the providing the fourth opening that penetrates through the isolation material layer is before the providing the first opening and the second opening that penetrate through the isolation material layer.

30. The manufacturing method of claim 20, wherein the providing the first opening and the second opening that penetrate through the isolation material layer further comprises: providing the fourth opening that penetrates through the isolation material layer; and
wherein after the disposing the second-type device within the second opening, the method further comprises: a fourth-type device is disposed within the fourth opening.
